(19) United States
(12) Patent Application Publication
(10) Pub. No.: US 2025/0366199 A1
(43) Pub. Date: Nov. 27, 2025

(54) DEVICE WITH ALTERNATE COMPLEMENTARY CHANNELS AND FABRICATION METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Shih-Ya LIN, Pingtung County (TW); Chien-Te TU, Hsinchu City (TW); Chung-En TSAI, Hsinchu County (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 19/293,433

(22) Filed: Aug. 7, 2025

Related U.S. Application Data
(63) Continuation of application No. 18/789,180, filed on Jul. 30, 2024.
Application No. 18/789,180 is a division of application No. 17/677,929, filed on Feb. 22, 2022.
(60) Provisional application No. 63/280,847, filed on Nov. 18, 2021.

(51) Int. Cl. H10D 84/85; H01L 21/02; H01L 21/306; H10D 30/01; H10D 30/67; H10D 62/10; H10D 64/01; H10D 84/01; H10D 84/03

(52) U.S. Cl. CPC H10D 84/856; H01L 21/0259; H01L 21/30604; H10D 30/031; H10D 30/6713; H10D 30/6729; H10D 30/6735; H10D 30/6757; H10D 62/118; H10D 64/017; H10D 64/018; H10D 84/0167; H10D 84/017; H10D 84/0184; H10D 84/0186; H10D 84/0188; H10D 84/038

(57) ABSTRACT

A device comprises a gate structure, n-type source/drain features, p-type source/drain features, an NFET channel, and a PFET channel. The gate structure is over a substrate. The n-type source/drain features are on opposite first and second sides of the gate structure, respectively. The p-type source/drain features are on opposite third and fourth sides of the gate structure, respectively. The NFET channel extends within the gate structure and connects the n-type source/drain features. The PFET channel extends within the gate structure and connects the p-type source/drain features. The NFET channel and the PFET channel are vertically spaced apart by the gate structure.

### PRIORITY CLAIM AND CROSS-REFERENCE

This application is a continuation of U.S. patent application Ser. No. 18/789,180, filed Jul. 30, 2024, which is a divisional of U.S. patent application Ser. No. 17/677,929, filed Feb. 22, 2022, which claims the benefit of U.S. Provisional Application No. 63/280,847, filed on Nov. 18, 2021, all of which are incorporated herein by reference in their entirety.

### BACKGROUND

Semiconductor devices are used in a variety of electronic applications, such as computers, cell phones, digital cameras, and other electronic equipment, as examples. Semiconductor devices are typically fabricated by sequentially depositing insulating or dielectric layers, conductive layers, and semiconductor layers of material over a semiconductor substrate, and patterning the various material layers using lithography to form circuit components and elements thereon.

A transistor is an element that is utilized extensively in semiconductor devices. There may be thousands of transistors on a single integrated circuit (IC) in some applications, for example. One common type of transistor used in semiconductor device fabrication is a metal oxide semiconductor field effect transistor (MOSFET). Two transistors may be coupled together to form an inverter.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic circuit diagram of an example CMOS inverter in accordance with some embodiments of the present disclosure.

FIGS. 2A-19C are top views, perspective views, and cross-sectional views of intermediate stages in the manufacturing of an inverter in accordance with some embodiments of the present disclosure.

FIGS. 20A and 20B are cross-sectional views of an inverter in accordance with some embodiments of the present disclosure, wherein FIG. 20A is obtained from a cut corresponding to cut A-A′ in FIG. 19A, and FIG. 20B is obtained from a cut corresponding to cut B-B′ in FIG. 19A.

FIGS. 21A and 21B are cross-sectional views of an inverter in accordance with some embodiments of the present disclosure, wherein FIG. 21A is obtained from a cut corresponding to cut A-A′ in FIG. 19A, and FIG. 21B is obtained from a cut corresponding to cut B-B′ in FIG. 19A.

FIGS. 22A and 22B are cross-sectional views of an inverter in accordance with some embodiments of the present disclosure, wherein FIG. 22A is obtained from a cut corresponding to cut A-A′ in FIG. 19A, and FIG. 22B is obtained from a cut corresponding to cut B-B′ in FIG. 19A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

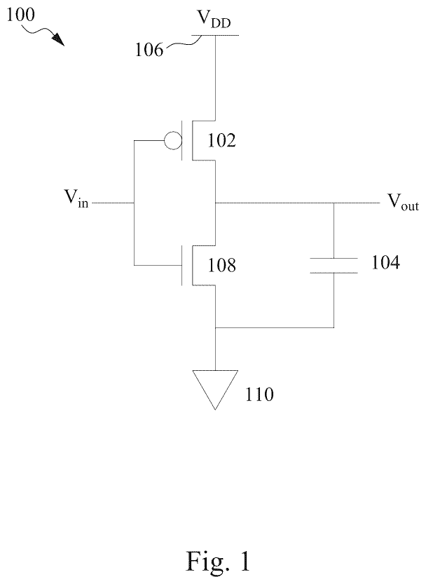

FIG. 1 is a schematic circuit diagram of an example complementary metal-oxide-semiconductor (CMOS) inverter 100 in accordance with some embodiments of the present disclosure. The example inverter 100 includes a p-type field effect transistor (PFET) 102 and an n-type field effect transistor (NFET) 108 coupled together. When the input voltage, Vin, to the inverter 100 is low, the p-type transistor 102 turns on, charges up a load capacitance 104, and the output goes to a gate drive 106, V_{DD}. Alternatively, when Vin is high, the n-type transistor 108 turns on, discharges the load capacitance, and the output node goes to ground 110 (e.g., V_{SS}). In this manner, the inverter 100 is able to perform the logic swing for digital processing. Because a CMOS inverter 100 includes two transistors formed on a same level height on wafer, it is challenging for scaling down footprint of inverters 100. Therefore, embodiments of the present disclosure are directed to a new structure of inverter having PFET channels and NFET channels alternately arranged along a vertical direction, which in turn reduces the footprint of inverters.

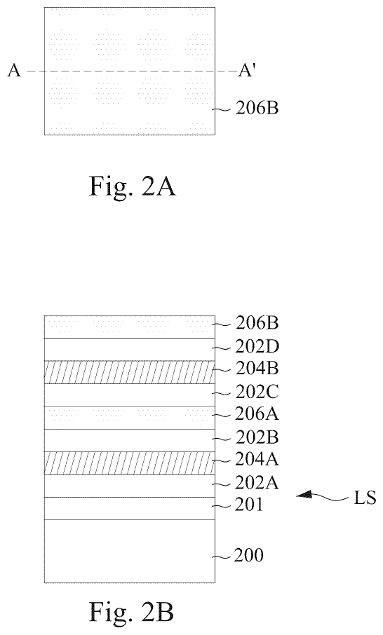

FIGS. 2A-19C are top views, perspective views, and cross-sectional views of intermediate stages in the manufacturing of an inverter in accordance with some embodiments of the present disclosure. The manufacturing process steps can be used to fabricate the inverter 100 as discussed with respect to FIG. 1. It is understood that additional operations can be provided before, during, and after processes shown by FIGS. 2A-19C, and some of the operations described below can be replaced or eliminated, for additional embodiments of the method. The order of the operations/processes may be interchangeable.

FIG. 2A is a top view of an intermediate stage in manufacturing of an inverter, and FIG. 2B is a cross-sectional view obtained from cut A-A′ in FIG. 2A. In FIGS. 2A and 2B, a substrate 200 is illustrated. In some embodiments, the substrate 200 may be a semiconductor substrate, such as a bulk semiconductor substrate, a semiconductor-on-insulator (SOI) substrate, a multi-layered or gradient substrate, or the like. The substrate 200 may include a semiconductor material, such as an elemental semiconductor including Si and Ge; a compound or alloy semiconductor including SiC, SiGe, GeSn, GaAs, GaP, GaAsP, AlInAs, AlGaAs, GalnAs, InAs, GalnP, InP, InSb, GaInAsP; a combination thereof, or the like. The substrate 200 may be doped or substantially un-doped. In a specific example, the substrate 200 is a bulk silicon substrate, which may be a wafer.

FIGS. 2A and 2B also illustrate a layer stack LS formed over the substrate 200. The layer stack LS may include one or more buffer layers 201 formed on the substrate 200. The buffer layer 201 can serve to gradually change the lattice constant from that of the substrate 200 to that of the epitaxial layers in the layer stack LS. The buffer layer 201 may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In some embodiments, the substrate 200 is made of Si, the buffer layer 201 is made of germanium. The buffer layer 201 is epitaxially grown on the substrate 200 by one or more epitaxy or epitaxial (epi) processes. The epitaxy processes include CVD deposition techniques (e.g., vapor-phase epitaxy (VPE) and/or ultra-high vacuum CVD (UHV-CVD)), molecular beam epitaxy (MBE), and/or other suitable processes.

A first semiconductor layer (also referred to as sacrificial layer in this context) 202A is formed over the buffer layer 201. A second semiconductor layer (also referred to as NFET channel layer) 204A is formed over the sacrificial layer 202A. Another first semiconductor layer (sacrificial layer) 202B is formed over the NFET channel layer 204A. A third semiconductor layer (also referred to as PFET channel layer) 206A is formed over the sacrificial layer 202B. Another first semiconductor layer (sacrificial layer) 202C is formed over the PFET channel layer 206A. Another second semiconductor layer (NFET channel layer) 204B is formed over the sacrificial layer 202C. Another first semiconductor layer (sacrificial layer) 202D is formed over the NFET channel layer 204B. Another third semiconductor layer (PFET channel layer) 206B is formed over the sacrificial layer 202D.

In some embodiments, the first, second and third semiconductor layers are alternately stacked such that there are more than two layers each of the first, second and third semiconductor layers. The first semiconductor layers 202A-202D (collectively referred to as first semiconductor layers 202) will be removed in subsequent processing and thus are referred to as sacrificial layers. The second semiconductor layers 204A and 204B (collectively referred to as second semiconductor layers 204) will become nanosheets, nanowires, nanoslabs or nanorings that connect n-type source/drain regions formed in subsequent processing, and will remain in a final IC product to serve as NEFT channel layers. The third semiconductor layers 206A and 206B (collectively referred to as third semiconductor layers 206) will become nanosheets, nanowires, nanoslabs or nanorings that connect p-type source/drain regions formed in subsequent processing, and will remain in a final IC product to serve as PEFT channel layers.

In some embodiments, the number of NFET channel layers 204 is from 1 to 20, and the number of PFET channel layers 206 is from 1 to 20. In some embodiments, the number of NFET channel layers 204 is the same as the number of PFET channel layers 206. In some embodiments, the number of NFET channel layers 204 is greater than the number of PFET channel layers 206. In some embodiments, the number of NFET channel layers 204 is less than the number of PFET channel layers 206. The number of NFET channel layers 204 and the number of PFET channel layers 206 can be selected to balance the current for the resultant inverter.

In some embodiments, the sacrificial layers 202, the NFET channel layers 204, and the PFET channel layers 206 are made of different materials selected from the group consisting of Si, Ge, Sn, SiGe, GeSn, Ge: B, SiGeSn, III-V compound, and combinations thereof. Because of the material difference, in subsequent processing, the NFET channel layers 204 can be selectively etched without substantially etching the sacrificial layers 202 and the PFET channels 206, the PFET channel layers 206 can be selectively etched without substantially etching the sacrificial layers 202 and the NFET channel layers 204, and the sacrificial layers 202 can be selectively etched without substantially etching the NFET channel layers 204 and the PFET channel layers 206. In some embodiments, the sacrificial layers 202 are pure germanium (Ge) layers without Si or Sn.

In some embodiments, the lattice constant of the PFET channel layers 206 is greater than the lattice constant of the NFET channel layers 204, and thus the PFET channel layers 206 have compressive strain and the NFET channel layers 204 have tensile strain. The compressive strain will increase hole mobility in the PFET channel layers 206, and the tensile strain will increase electron mobility in the NFET channel layers 204. In some embodiments, the NFET channel layers 204 are germanium silicon (GeSi) layers, and the PFET channel layers 206 are germanium tin (GeSn) layers. In some embodiments, the NFET channel layers 204 are boron-doped germanium (Ge: B) layers, and the PFET channel layers 206 are un-doped GeSi layers. In some embodiments, the NFET channel layers 204 are Si layers without Ge, and the PFET channel layers 206 are GeSi layers. In some embodiments, the NFET channel layers 204 are Ge layers without Sn, and the PFET channel layers 206 are un-doped GeSn layers.

In some embodiments, a thickness of each NFET channel layer 204 is smaller than a critical thickness of the epitaxial material of the NFET channel layer 204, and a thickness of each PFET channel layer 206 is smaller than a critical thickness of the epitaxial material of the PFET channel layer 206. As used herein, a “critical thickness” refers to a thickness that an epitaxial layer can keep to maintain the elastic strain energy below the energy of dislocation formation. When the film thickness is below the critical thickness, the elastically strained-layer is thermodynamically stable against dislocation formation. Because thickness of each NFET channel layer 204 is smaller than its critical thickness, and thickness of each PFET channel layer 206 is smaller than its critical thickness, the NFET channel layers 204 keep tensile-strained with no or negligible strain relaxation, and the PFET channel layers 206 keep compressive-strained with no or negligible strain relaxation. In some embodiments, the NFET channel layers 204 and PFET channel layers 206 each have a thickness in a range from about 1 nm to about 50 nm.

In some embodiments, the sacrificial layers 202 serve to define the spacing between adjacent two of the NFET channel layers 204 and PFET channel layers 206. For example, the spacing between the NFET channel layer 204A and the PFET channel layer 206A can be adjusted by the sacrificial layer 202B, the spacing between the NFET channel layer 204B and the PFET channel layer 206A can be adjusted by the sacrificial layer 202C, and the spacing between the PFET channel layer 206B and the NFET channel layer 204B can be adjusted by the sacrificial layer 202D. Therefore, the thickness of sacrificial layers 202 depends on a target distance between adjacent NFET channel and PFET channel. For example, the sacrificial layers 202 each have a thickness in a range from about 1 nm to about 50 nm.

The sacrificial layers 202, the NFET channel layers 204, and the PFET channel layers 206 may be formed by one or more epitaxy or epitaxial (epi) processes. The epitaxy processes include CVD deposition techniques (e.g., vapor-phase epitaxy (VPE) and/or ultra-high vacuum CVD (UHV-CVD)), molecular beam epitaxy (MBE), and/or other suitable processes.

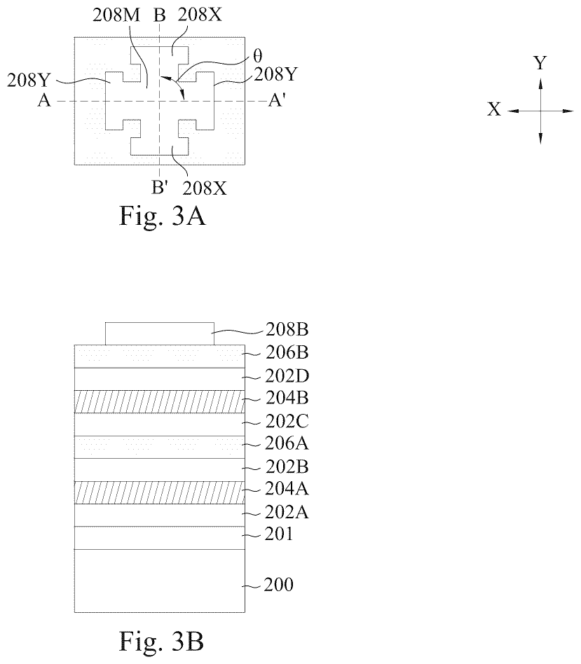

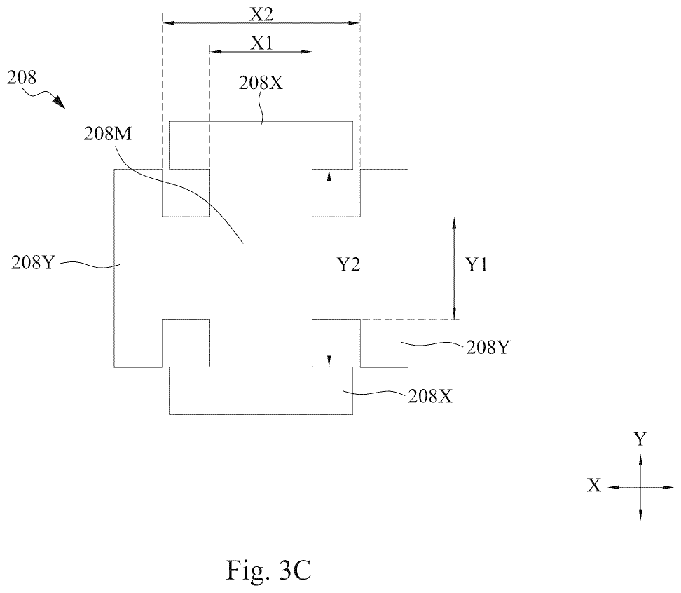

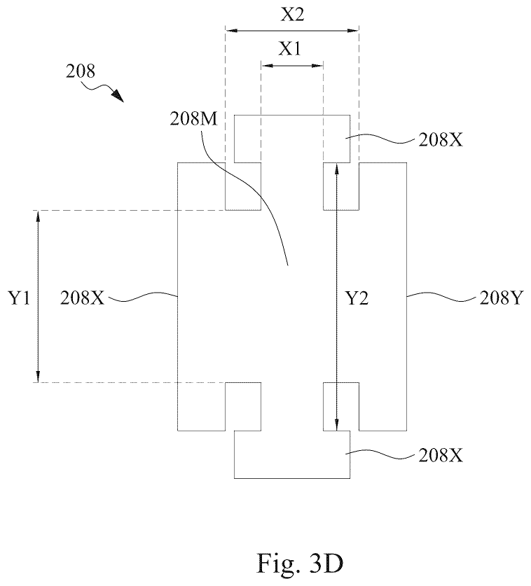

FIG. 3A is a top view of an intermediate stage in manufacturing of the inverter that is subsequent to the stage shown in FIG. 2A, and FIG. 3B is a cross-sectional view obtained from cut A-A′ or cut B-B′ in FIG. 3A. In FIGS. 3A and 3B, a patterned mask 208 is formed over the topmost PFET channel layer 206B. In some embodiments, the patterned mask 208 includes silicon nitride (Si₃N₄), silicon oxycarbide (SiOC), silicon oxide, the like, or combinations thereof. The patterned mask 208 may be formed by, for example, depositing a layer of mask material (e.g., silicon nitride) over the layer stack LS, coating a photoresist layer over the layer of mask material, patterning the photoresist layer into a photoresist mask by using a photolithography process, and etching the layer of mask material to form the patterned mask 208 by using the photoresist mask as an etch mask.

As illustrated in the top view of FIG. 3A, the patterned mask 208 has a cross-shaped pattern 208M, a pair of X-directional linear patterns 208X extending along X-direction at upper and lower ends of the cross-shaped pattern 208M, and a pair of Y-directional linear patterns 208Y extending along Y-direction at left and right ends of the cross-shaped pattern 208M. The X-directional linear patterns 208X correspond to top-view patterns of subsequently formed n-type source/drain regions. The Y-directional linear patterns 208Y correspond to top-view patterns of subsequently formed p-type source/drain regions. In some embodiments, the cross angle θ of the cross-shaped pattern 208M is in a range up to about 90 degrees.

FIG. 3C is a zoomed-in top view of the patterned mask 208. The cross-shaped pattern 208M has an X-directional width X1 at a boundary between the cross-shaped pattern 208M and the X-directional linear pattern 208X. The X-directional width X1 corresponds to channel width of subsequently formed NFET channels, and is in a range, e.g., from about 0.1 nm to about 100 μm. The cross-shaped pattern 208M has a Y-directional width Y1 at a boundary between the cross-shaped pattern 208M and the Y-directional linear pattern 208X. The Y-directional width Y1 corresponds to channel width of subsequently formed PFET channels, and is in a range, e.g., from about 0.1 nm to about 100 μm. In some embodiments, the X-directional width X1 is the same as the Y-directional width Y1, and thus the subsequently formed NFET channels have a same channel width as the subsequently formed PFET channels. In some other embodiments, the X-directional width X1 is different from the Y-directional width Y1, and thus the subsequently formed NFET channels have a different channel width from the subsequently formed PFET channels. For example, when the X-directional width X1 is greater than the Y-directional width Y1, the subsequently formed NFET channels will have a larger channel width than the subsequently formed PFET channels; when the X-directional dimension X1 is less than the Y-directional dimension Y1, the subsequently formed NFET channels will have a smaller channel width than the subsequently formed PFET channels. Resultantly, the X-directional dimension X1 of the cross-shaped pattern 208M can be selected to adjust NFET channel width and hence NFET gate length (Lg), and the Y-directional dimension Y1 of the cross-shaped pattern 208M can be selected to adjust PFET channel width and hence PFET gate length (Lg), which in turn will aid in tuning currents of NFET and PFET.

In FIG. 3C, the cross-shaped pattern 208M of the patterned mask 208 has an X-directional length X2 extending from a first one of the Y-directional linear pattern 208Y to a second one of the Y-directional linear pattern 208Y. The X-directional length X2 of the cross-shaped pattern 208M corresponds to channel length of subsequently formed PFET channels. The cross-shaped pattern 208M of the patterned mask 208 has a Y-directional length Y2 extending from a first one of the X-directional linear pattern 208X to a second one of the X-directional linear pattern 208X. The Y-directional length Y2 of the cross-shaped pattern 208M corresponds to channel length of subsequently formed NFET channels. In the illustrated embodiment in FIG. 3C, the cross-shaped pattern 208M has X-directional width X1 same as Y-directional width Y1, and X-directional length X2 same as Y-directional length Y2. In some other embodiments, the cross-shaped pattern 208M has different dimensions. For example, in another example of patterned mask 208 as illustrated in FIG. 3D, the cross-shaped pattern 208M has the Y-directional width Y1 greater than the X-directional width X1, and the X-directional length X2 less than the Y-directional length Y2. In such embodiments, the channel width of subsequently formed PFET channel structures (corresponding to Y-directional width Y1) is larger than the channel width of subsequently formed NFET channel structures (corresponding to X-directional width X1), and the channel length of the PFET channel structures (corresponding to the X-directional length X2) is shorter than the channel length of the NFET channel structures (corresponding to the Y-directional length Y2). The dimensions X1, X2, Y1 and Y2 can be selected to make sure that the total current of subsequently formed PFET and NFET is appropriate.

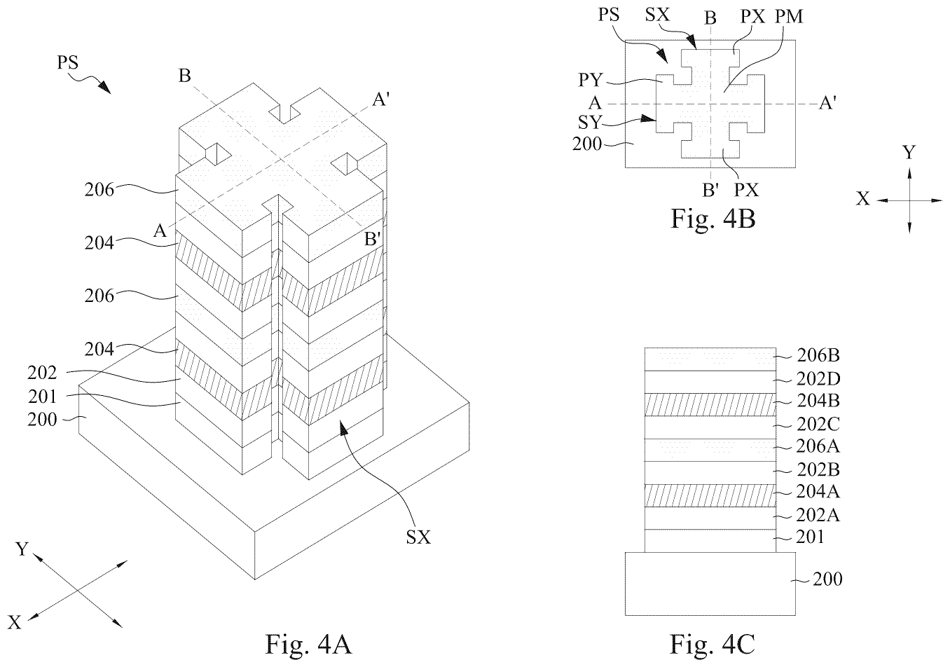

FIG. 4A is a perspective view of an intermediate stage in manufacturing of the inverter that is subsequent to the stage shown in FIG. 3A, FIG. 4B is a top view of the structure illustrated in FIG. 4A, and FIG. 4C is a cross-sectional view obtained from cut A-A′ or cut B-B′ in FIG. 4A. In FIGS. 4A-4C, the layer stack is patterned into a patterned layer stack PS by one or more etching processes using the patterned mask 208 as an etch mask. The one or more etching processes may include wet etching processes, anisotropic dry etching processes, or combinations thereof, and may use one or more etchants that etch the sacrificial layers 202, the NFET channel layers 204, and the PFET channel layers 206 at a faster etch rate than etching the patterned mask 208. The top-view pattern of patterned mask 208 is thus transferred to underlying layers, and hence each layer (including the buffer layer 201, the sacrificial layers 202, the NFET channel layers 204, and the PFET channel layers 206) in the resultant patterned stack PS inherits the top-view pattern of the patterned mask 208, which includes a cross-shaped pattern PM, a pair of X-directional linear patterns PX at upper and lower ends of the cross-shaped pattern, and a pair of Y-directional linear patterns PY at left and right ends of the cross-shaped pattern, as previously described in detail with respect to FIGS. 3C-3D. Therefore, the resultant patterned layer stack PS has Y-directional sidewalls SY extending along the Y-direction on left and right sides of the patterned stack PS, and X-directional sidewalls SX extending along the X-direction on upper and lower sides of the patterned stack PS, when viewed in a top view of FIG. 4B. Although the patterned stack PS illustrated in FIGS. 4A-4C has vertical sidewalls in cross-sectional view as illustrated in FIG. 4C, the etching process may lead to tapered sidewalls in some other embodiments, such that each layer in the patterned stack PS has a width decreasing as a distance from the substrate 200 increases. In some embodiments, the sacrificial layers 202, the NFET channel layers 204 and the PFET channel layers 206 in the patterned stack PS has a width (i.e., largest linear dimension from top view) in a range from about 1 nm to about 500 nm.

In some embodiments, the patterned stack PS is formed by anisotropic dry etching. Take plasma etching as an example of the anisotropic dry etching, the substrate 200 having the structure illustrated in FIGS. 3A-3B is loaded in to a plasma tool and exposed to a plasma environment generated by RF or microwave power in a gaseous mixture of one or more of chlorine-based gas (e.g., Cl₂, SiCl₄, or the like), a fluorine-based gas (such as CF₄, SF₆, CH₂F₂, CH₃F, CHF₃, or the like), and hydrogen bromide gas (HBr) for a duration time sufficient to expose the substrate 200, while causing no or negligible loss in the patterned mask 208. The plasma etching may be performed, by way of example and not limitation, at an RF power between about 1 and about 1000 Watts (e.g., 150 Watts). Once the etching process is complete, the patterned mask 208 can be removed by using a selective wet etching process using, for example, H₃PO₄ or other suitable etchants that can selectively etch the nitride material of the patterned mask 208.

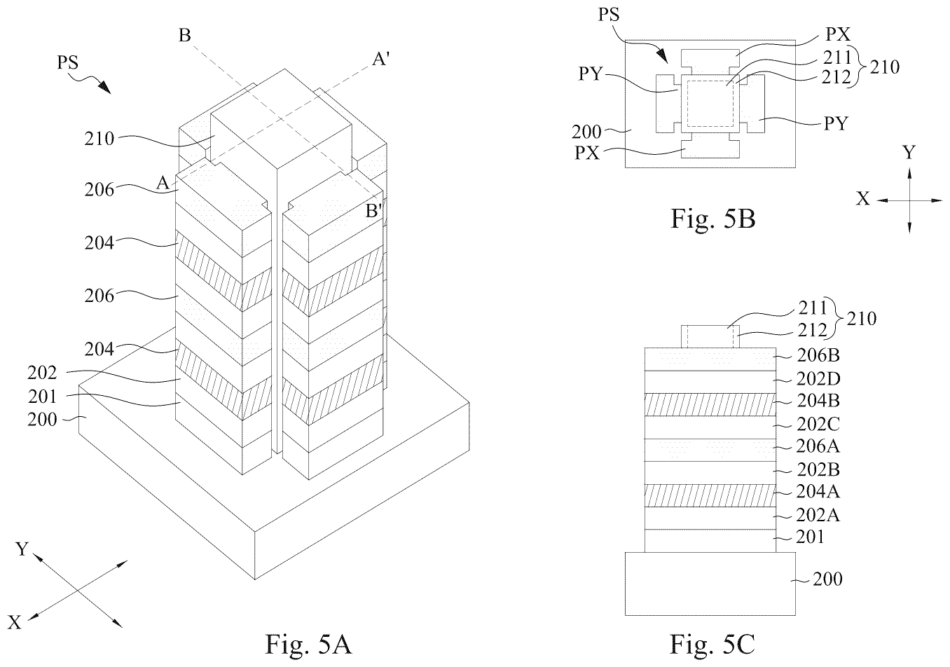

FIG. 5A is a perspective view of an intermediate stage in manufacturing of the inverter that is subsequent to the stage shown in FIG. 4A, FIG. 5B is a top view of the structure illustrated in FIG. 5A, and FIG. 5C is a cross-sectional view obtained from cut A-A′ or cut B-B′ in FIG. 5A. In FIGS. 5A-5C, dummy gate structure 210 is formed over the patterned stack PS. The dummy gate structure 210 have four sides respectively set back from the Y-directional linear patterns PY and the X-directional linear patterns PX, and thus the Y-directional linear patterns PY exposed by the dummy gate structure 210 can be replaced with p-type source/drain epitaxial structures in subsequent processing, and the X-directional linear patterns PX exposed by the dummy gate structure 210 can be replaced with n-type source/drain epitaxial structures in subsequent processing. Therefore, the Y-directional linear patterns PY can be interchangeably referred to as PFET source/drain regions in the patterned stack PS, and the X-directional linear patterns PX can be interchangeably referred to as NFET source/drain regions in the patterned stack PS. In some embodiments as illustrated in FIG. 5B, the dummy gate structure 210 has a square top-view profile. In some other embodiments, the dummy gate structure 210 may have a rectangular top-view profile with a longest linear dimension in the X-direction or the Y-direction.

In some embodiments, the dummy gate structure 210 includes a dummy gate 211 which may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gate 211 may be deposited by physical vapor deposition (PVD), CVD, sputter deposition, or the like. The dummy gate 211 can be formed by, for example, depositing a dummy gate material over the substrate 200 by using physical vapor deposition (PVD), CVD, sputter deposition, or the like, followed by planarizing the dummy gate material, such as by a chemical mechanical polish (CMP) process. Afterwards, the planarized dummy gate material is patterned by using suitable photolithography and etching techniques.

As illustrated in FIGS. 5B and 5C, gate spacers 212 are formed on sidewalls of the dummy gate 211. In some embodiments of the spacer formation step, a spacer material layer is deposited on the substrate 200. The spacer material layer may be a conformal layer that is subsequently etched back to form gate sidewall spacers. In the illustrated embodiment, a spacer material layer is disposed conformally on top and sidewalls of the dummy gate 211. The spacer material layer may include a dielectric material such as silicon nitride, silicon oxide, silicon carbide, silicon oxynitride, SiCN films, silicon oxycarbide, SiOCN films, and/or combinations thereof. The spacer material layer may be formed by depositing a dielectric material over the dummy gate 211 using processes such as, CVD process, a subatmospheric CVD (SACVD) process, a flowable CVD process, an ALD process, a PVD process, or other suitable process. An anisotropic etching process is then performed on the deposited spacer material layer to expose portions of the patterned stack PS not covered by the dummy gate 211 (e.g., in PFET source/drain regions PY and NFET source/drain regions PX of the patterned stack PS). Portions of the spacer material layer directly above the dummy gate 211 may be completely removed by this anisotropic etching process. Portions of the spacer material layer on sidewalls of the dummy gate 211 may remain, forming gate sidewall spacers, which is denoted as the gate spacers 212, for the sake of simplicity.

In some embodiments, as illustrated in the top view of FIG. 5B, four gate spacers 212 are respectively formed on four sides of the square-shaped dummy gate 211. These gate spacers 212 are connected as a square ring-shaped spacer that encloses the square-shaped dummy gate 211 when viewed from a top view as illustrated in FIG. 5B. Therefore, when viewed in a top view as illustrated in FIG. 5B, the ring-shaped spacer 212 can separate the dummy gate 211 apart from the PFET source/drain regions PY on the left and right sides of the dummy gate 211, and also separate the dummy gate 211 apart from the NFET source/drain regions PX on the upper and lower sides of the dummy gate 211. It is understood that discussion about the square shape of the dummy gate structure and the square ring shape of the gate spacer are illustrative only, and other embodiments of the present disclosure may include a rectangular dummy gate structure and a rectangle ring-shaped spacer enclosing the rectangular dummy gate structure. The dummy gate 211 and its surrounding gate spacers 212 can be collectively referred to as a dummy gate structure 210 in this context. For the sake of simplicity and clarity, the dash lines indicating potential boundaries between the dummy gate 211 and gate spacers 212 are illustrated in FIGS. 5B and 5C only, and will not be illustrated in figures about subsequent steps.

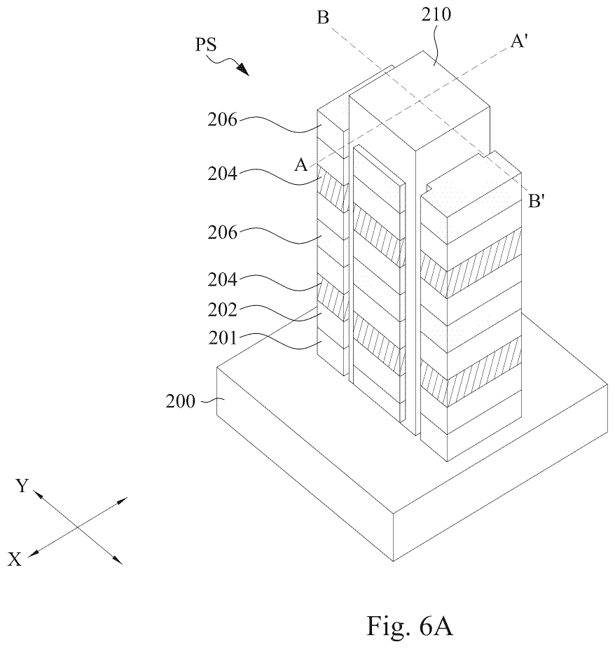

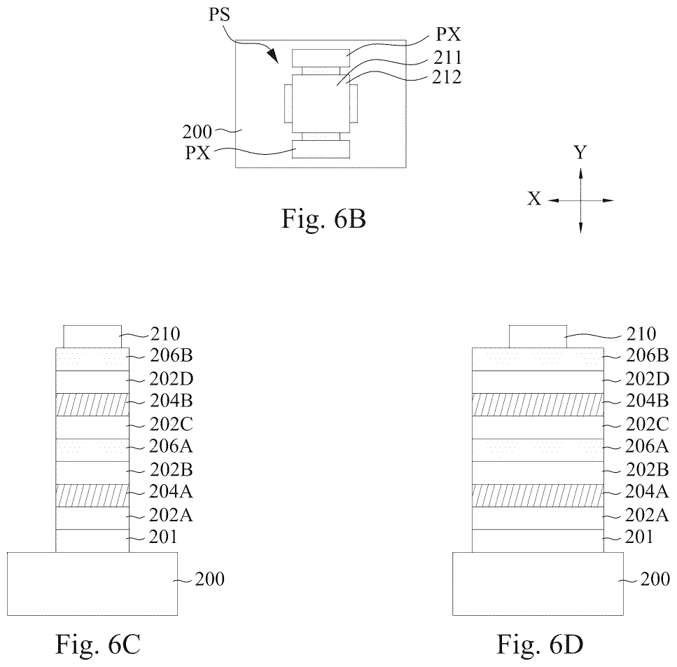

FIG. 6A is a perspective view of an intermediate stage in manufacturing of the inverter that is subsequent to the stage shown in FIG. 5A, FIG. 6B is a top view of the structure illustrated in FIG. 6A, FIG. 6C is a cross-sectional view obtained from cut A-A′ in FIG. 6A, and FIG. 6D is a cross-sectional view obtained from cut B-B′ in FIG. 6A. In FIGS. 6A-6D, the PFET source/drain regions PY in the patterned stack PS that extend laterally beyond the dummy gate structure 210 along X-direction are removed, for example, in an anisotropic etch step until the substrate 200 is exposed. The etching is performed using an etchant that attacks the patterned stack PS, and hardly attacks the dummy gate structure 210. Stated differently, the dummy gate structure 210 has higher etch resistance to the etching process than that of the patterned stack PS. Accordingly, in the etching step, the height of dummy gate structure 210 is substantially not reduced. In some embodiments, the etching step is performed with an etch mask (e.g., photoresist mask and/or nitride mask) formed over the NFET source/drain regions PX, so as to allow the etching step etching the PFET source/drain regions PY, while leaving the NFET source/drain regions PX intact.

In some embodiments, removal of the PFET source/drain regions PY can be performed using anisotropic dry etching. Take plasma etching as an example of the anisotropic dry etching, the PFET source/drain regions PY can be etched by a plasma environment generated by RF or microwave power in a gaseous mixture of one or more of chlorine-based gas (e.g., Cl₂, SiCl₄, or the like), a fluorine-based gas (such as CF₄, SF₆, CH₂F₂, CH₃F, CHF₃, or the like), and hydrogen bromide gas (HBr) for a duration time sufficient to expose portions of the substrate 200 under the PFET source/drain regions PY. At this stage, because the PFET source/drain regions PY has been removed but the NFET source/drain regions PX remain in the patterned stack PS, each layer in the patterned stack PS has a longer dimension in Y-direction than in X-direction.

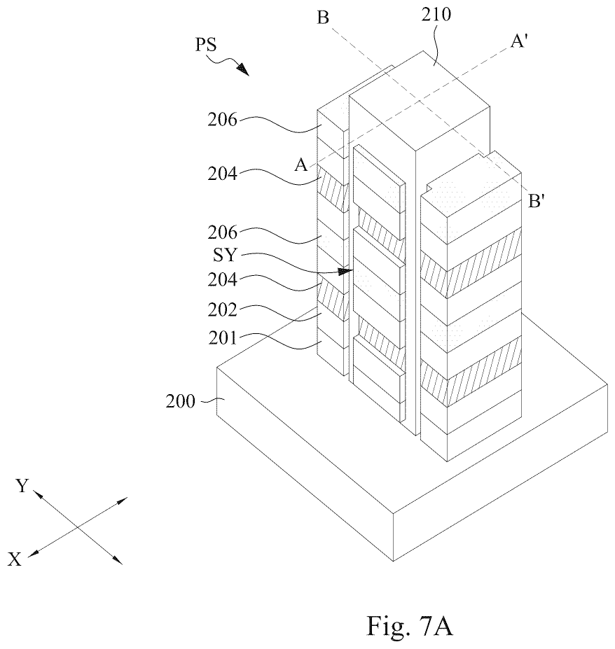

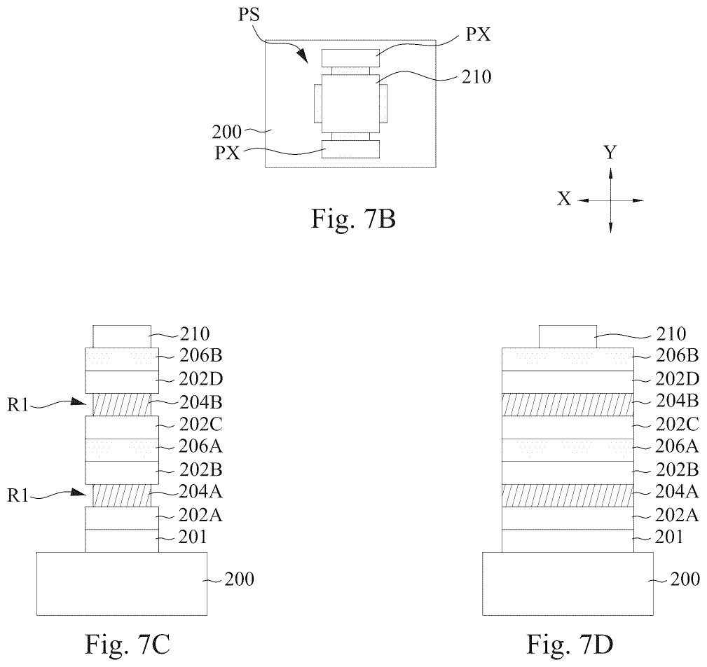

FIG. 7A is a perspective view of an intermediate stage in manufacturing of the inverter that is subsequent to the stage shown in FIG. 6A, FIG. 7B is a top view of the structure illustrated in FIG. 7A, FIG. 7C is a cross-sectional view obtained from cut A-A′ in FIG. 7A, and FIG. 7D is a cross-sectional view obtained from cut B-B′ in FIG. 7A. In FIGS. 7A-7D, Y-directional sidewalls of the NFET channel layers 204 exposed by the removal of PFET source/drain regions PY in the previous step are laterally recessed by suitable etching technique to form sidewall recesses R1 between corresponding sacrificial layers 202. Although sidewalls of the NFET channel layers 204 in the recesses R1 are illustrated as being straight in FIG. 7C, the sidewalls may be concave or convex. In some embodiments, the etching step is a selective etching step performed with an etch mask (e.g., photoresist mask and/or nitride mask) formed over the NFET source/drain regions PX, so that portions of the NFET channel layers 204 in the NFET source/drain regions PX remain substantially intact without being laterally recessed. Stated differently, the selective etching is performed to only the Y-directional sidewalls SY of the patterned stack PS by using a patterned mask that exposes the Y-directional sidewalls of the patterned stack PS only.

In some embodiments where the NFET channel layers 204 are GeSi, and the PFET channel layers 206 are GeSn, the NFET channel layers 204 can be laterally etched by using a selective etching process that etches GeSi at a faster etch rate than etching GeSn. For example, the NFET channel layers 204 formed of GeSi can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch GeSi at a faster etch rate than etching GeSn. By way of example, the GeSi selective etching step may be an isotropic dry etching process using CF₄ as a main precursor gas and performed at a flow rate of the using CF₄ gas in a range from about 1 standard cubic centimeters per minute (sccm) to about 100 sccm (e.g., 300 sccm), at RF power in a range from about 0 W to about 1000 W (e.g., 700 W), and at a pressure in a range from about 0 torr to about 300 torr (e.g., 350 mtorr).

In some embodiments where the NFET channel layers 204 are Ge: B, and the PFET channel layers 206 are un-doped GeSi or GeSn, the NFET channel layers 204 can be laterally etched by using a selective etching process that etches Ge: B at a faster etch rate than etching un-doped GeSi or GeSn. For example, the NFET channel layers 204 formed of Ge: B can be selectively etched by a plasma etching using plasmas generated from a fluorine-based gas (such as CF₄, NF₃, or the like), an oxygen gas (e.g., O₂), and/or a nitrogen gas (e.g., N₂), because the etch rate increases as boron concentration increases in the foregoing etching chemistry.

In some embodiments where the NFET channel layers 204 are Si, and the PFET channel layers 206 are GeSi, the NFET channel layers 204 can be laterally etched by using a selective etching process that etches Si at a faster etch rate than etching GeSi. For example, the NFET channel layers 204 formed of Si can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch Si at a faster etch rate than etching GeSi. In some other embodiments, the NFET channel layers 204 formed of Si can be selectively etched by a wet etching process using tetramethylammonium hydroxide (TMAH) as the wet etchant.

In some embodiments where the NFET channel layers 204 are Ge, and the PFET channel layers 206 are GeSn, the NFET channel layers 204 can be laterally etched by using a selective etching process that etches Ge at a faster etch rate than etching GeSn. For example, the NFET channel layers 204 formed of Ge can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch Ge at a faster etch rate than etching GeSn. By way of example, the Ge selective etching step may be an isotropic dry etching process using NF₃ as a main precursor gas and performed at a flow rate of the using NF₃ gas in a range from about 1 standard cubic centimeters per minute (sccm) to about 100 sccm (e.g., 7 sccm), at a chamber temperature in a range from about 0 degrees Centigrade to about 100 degrees Centigrade (e.g., 14 degrees Centigrade), and at a pressure in a range from about 1 torr to about 100 torr (e.g., 7 torr).

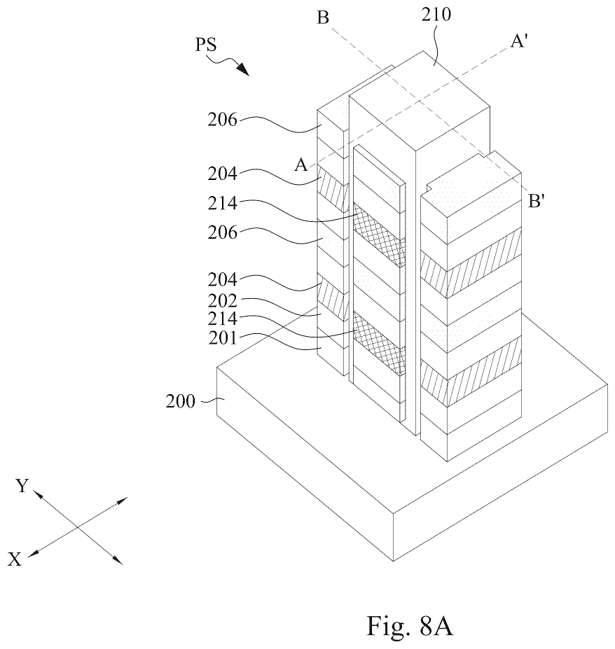

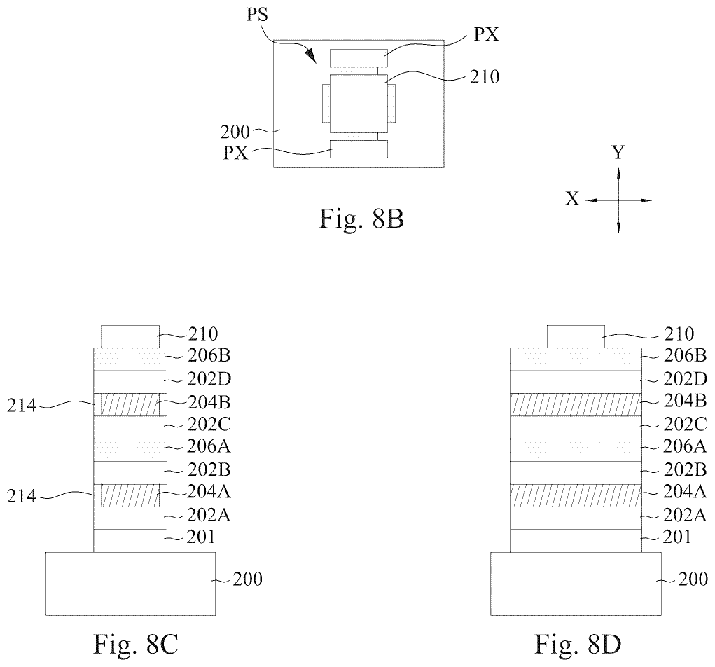

FIG. 8A is a perspective view of an intermediate stage in manufacturing of the inverter that is subsequent to the stage shown in FIG. 7A, FIG. 8B is a top view of the structure illustrated in FIG. 8A, FIG. 8C is a cross-sectional view obtained from cut A-A′ in FIG. 8A, and FIG. 8D is a cross-sectional view obtained from cut B-B′ in FIG. 8A. In FIGS. 8A-8D, after the NFET channel layers 204 are laterally recessed, PFET inner spacers 214 are formed in the sidewall recesses R1. The PFET inner spacers 214 act as isolation features between subsequently formed PFET source/drain epitaxial structures and NFET channel layers 204.

Inner spacers 214 are formed from an inner spacer layer that is deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 214. Although outer sidewalls of the inner spacers 214 are illustrated as being flush with sidewalls of the PFET channel layers 206 and sacrificial layers 202, the outer sidewalls of the inner spacers 214 may extend beyond or be recessed from sidewalls of the PFET channel layers 206 and sacrificial layers 202. Moreover, although the outer sidewalls of the inner spacers 214 are illustrated as being straight in FIGS. 8A and 8C, the outer sidewalls of the inner spacers 214 may be concave or convex. The inner spacer layer may be etched by an anisotropic etching process, such as RIE, NBE, or the like. In some embodiments, the inner spacers 214 has a thickness in a range from about 0.1 nm to about 50 nm.

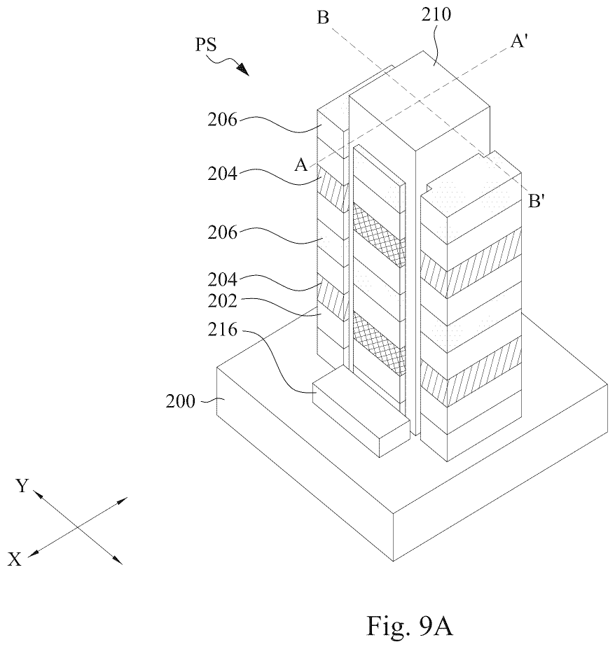

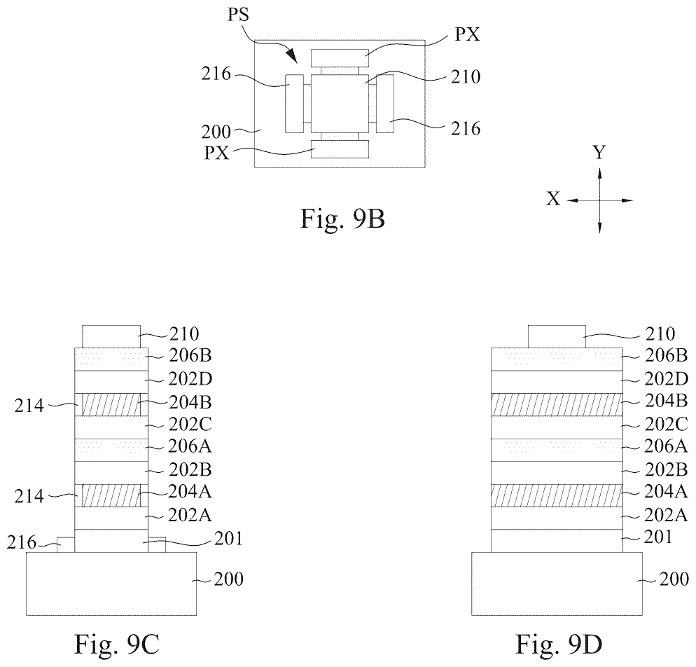

FIG. 9A is a perspective view of an intermediate stage in manufacturing of the inverter that is subsequent to the stage shown in FIG. 8A, FIG. 9B is a top view of the structure illustrated in FIG. 9A, FIG. 9C is a cross-sectional view obtained from cut A-A′ in FIG. 9A, and FIG. 9D is a cross-sectional view obtained from cut B-B′ in FIG. 9A. In FIGS. 9A-9D, bottom dielectric isolation structures 216 are formed on the substrate 200. In some embodiments, the bottom dielectric isolation structures 216 are localized to areas of previously removed PFET source/drain regions PY. In some other embodiments, the bottom dielectric isolation structures 216 cover all exposed areas of the substrate 200. The bottom dielectric isolation structures 216 can serve to electrically isolate the subsequently formed p-type source/drain epitaxial structures from the underlying substrate 200, which in turn will avoid unwanted leakage current in substrate 200 and hence unwanted shorting between source/drain epitaxial structures.

In some embodiments, the bottom dielectric isolation structures 216 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials formed by any acceptable process may be used. Once the dielectric material is deposited, the dielectric material can be selectively etched back to fall below the bottommost one of the PFET channel layers 206, which in turn allows for epitaxially growing p-type source/drain structures from the exposed surfaces of the PFET channel layers 206 directly above the bottom dielectric isolation structures 216. In some embodiments, the etched back dielectric material is patterned by using suitable photolithography and etching techniques to form bottom dielectric isolation structures 216 localized to the areas of previously removed PFET source/drain regions PY.

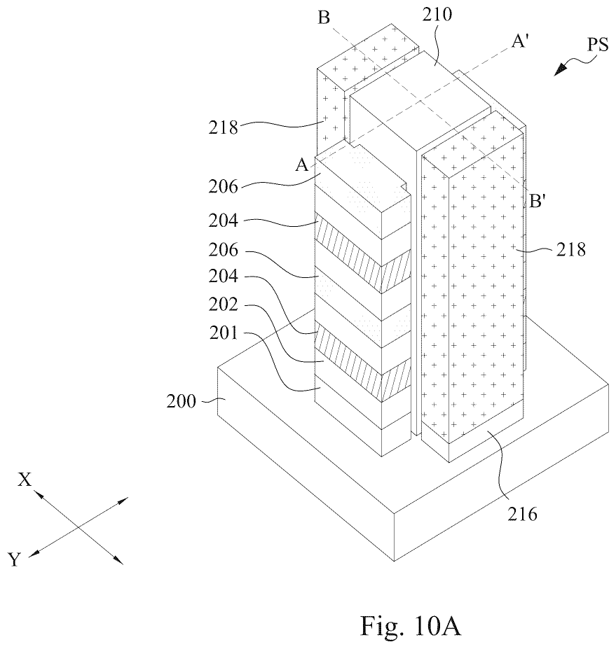

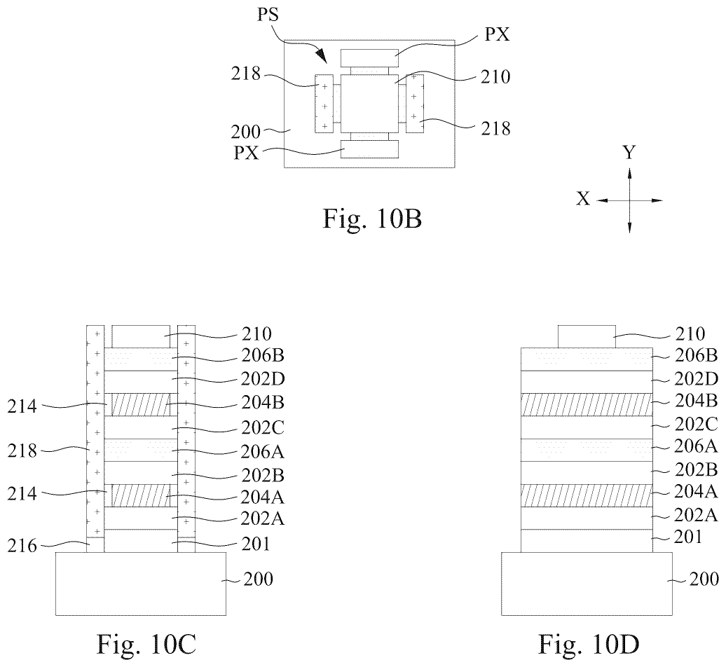

FIG. 10A is a perspective view of an intermediate stage in manufacturing of the inverter that is subsequent to the stage shown in FIG. 9A, FIG. 10B is a top view of the structure illustrated in FIG. 10A, FIG. 10C is a cross-sectional view obtained from cut A-A′ in FIG. 10A, and FIG. 10D is a cross-sectional view obtained from cut B-B′ in FIG. 10A. It understood that the perspective view of FIG. 10A and perspective views of following steps are depicted in a different viewing angle from the previous perspective views (e.g., 4A, 5A, 6A, 7A, 8A, and 9A) for the sake of clarity. In FIGS. 10A-10D, p-type epitaxial source/drain structures 218 are formed on the previously removed PFET source/drain regions PY, and the PFET channel layers 206 continuously extend from a first one of the p-type epitaxial source/drain structures 218 to a second one of the p-type epitaxial source/drain structures 218. In some embodiments, the p-type epitaxial source/drain structures 218 may exert compressive strain on the PFET channel layers 206, thereby improving PFET device performance. The p-type epitaxial source/drain structures 218 are spaced apart along X-direction, with the dummy gate structure 210 there-between. In some embodiments, the p-type epitaxial source/drain structures 218 are spaced apart from the dummy gate structure 210 because the dummy gate structure 210 have opposite sidewalls laterally set back from the respective sidewalls of the PFET channel layer 206. In some embodiments, the inner spacers 214 are used to separate the p-type epitaxial source/drain structures 218 from the NFET channel layers 204 by an appropriate lateral distance so that the p-type epitaxial source/drain structures 218 do not short out with the NFET channel layers 204.

In some embodiments, the epitaxial source/drain structures 218 may include any acceptable material appropriate for PFET. For example, if the PFET channel layers 206 are Ge₁₋ₓSnₓ, the p-type epitaxial source/drain structures 218 may comprise materials exerting a compressive strain on the PFET channel layers 206, such as Ge_{1-y}Sn_{y}, wherein y>x. In some embodiments, the epitaxial source/drain structures 218 include Si, Ge, Sn, Si₁₋ₓGeₓ, Si_{1-x-y}GeₓSn_{y}, III-V compound, or the like. In some embodiments, the epitaxial growth is performed with a patterned mask formed over the substrate 200 except for the target regions directly above bottom dielectric isolation structures 216. As a result, the epitaxial growth takes place only on exposed surfaces of the PFET channel layers 206 and the sacrificial layers 202 that are exposed in the regions directly above the bottom dielectric isolation structures 216, which in turn prevents the semiconductor layers in NFET source/drain regions PX from unwanted epitaxial growth. In some embodiments, the epitaxy growth may be performed using CVD deposition techniques (e.g., vapor-phase epitaxy (VPE) and/or ultra-high vacuum CVD (UHV-CVD)), molecular beam epitaxy (MBE), and/or other suitable processes. In some embodiments, the p-type epitaxial source/drain structures 218 each has a thickness in a range from about 1 nm to about 100 μm.

The p-type epitaxial structures 218 may be implanted with a p-type dopant (e.g., boron or gallium) to form p-type source/drain structures 218, followed by an anneal process. The source/drain structures 218 may have an p-type impurity (e.g., boron or gallium) concentration of between about 1×10¹⁷ atoms/cm³ and about 1×10²² atoms/cm³. In some embodiments, the p-type epitaxial structures 218 may be in situ doped with the p-type dopant during growth.

FIG. 11A is a perspective view of an intermediate stage in manufacturing of the inverter that is subsequent to the stage shown in FIG. 10A, FIG. 11B is a top view of the structure illustrated in FIG. 11A, FIG. 11C is a cross-sectional view obtained from cut A-A′ in FIG. 11A, and FIG. 11D is a cross-sectional view obtained from cut B-B′ in FIG. 11A. In FIGS. 11A-11D, the NFET source/drain regions PX in the patterned stack PS that extend laterally beyond the dummy gate structure 210 are removed, for example, in an anisotropic etch step until the substrate 200 is exposed. The etching is performed using an etchant that attacks the patterned stack PS, and hardly attacks the dummy gate structure 210. Stated differently, the dummy gate structure 210 has higher etch resistance to the etching process than that of the patterned stack PS. Accordingly, in the etching step, the height of dummy gate structure 210 is substantially not reduced. In some embodiments, the etching step is performed with an etch mask (e.g., photoresist mask and/or nitride mask) formed over the p-type epitaxial source/drain structures 218, so as to allow the etching step etching the NFET source/drain regions PX, while leaving the p-type epitaxial source/drain structures 218 intact.

In some embodiments, removal of the NFET source/drain regions PX can be performed using anisotropic dry etching. Take plasma etching as an example of the anisotropic dry etching, the NFET source/drain regions PX can be etched by a plasma environment generated by RF or microwave power in a gaseous mixture of one or more of chlorine-based gas (e.g., Cl₂, SiCl₄, or the like), a fluorine-based gas (such as CF₄, SF₆, CH₂F₂, CH₃F, CHF₃, or the like), and hydrogen bromide gas (HBr) for a duration time sufficient to expose portions of the substrate 200 under the NFET source/drain regions PX.

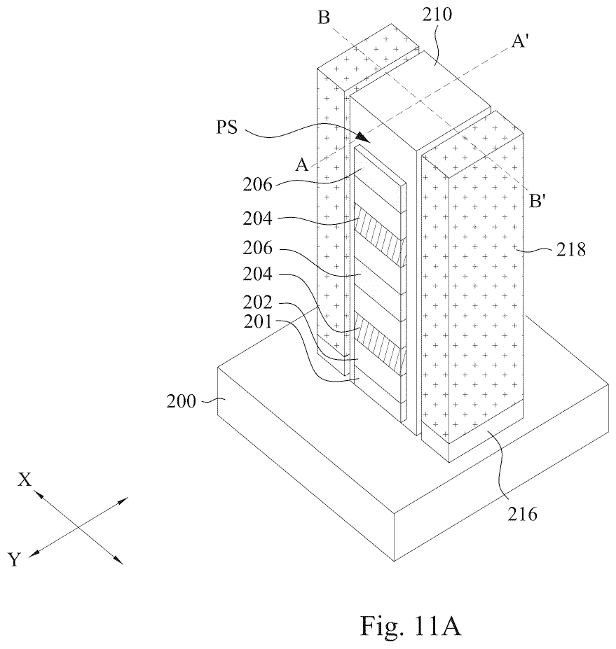

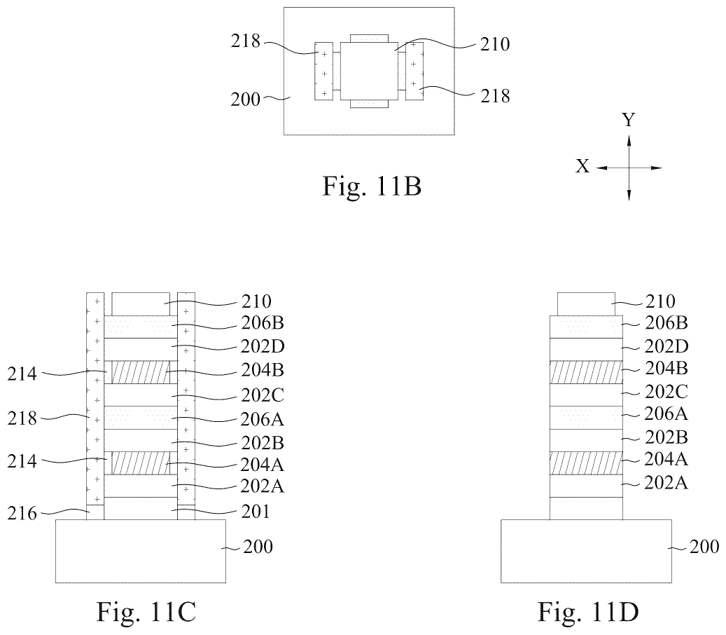

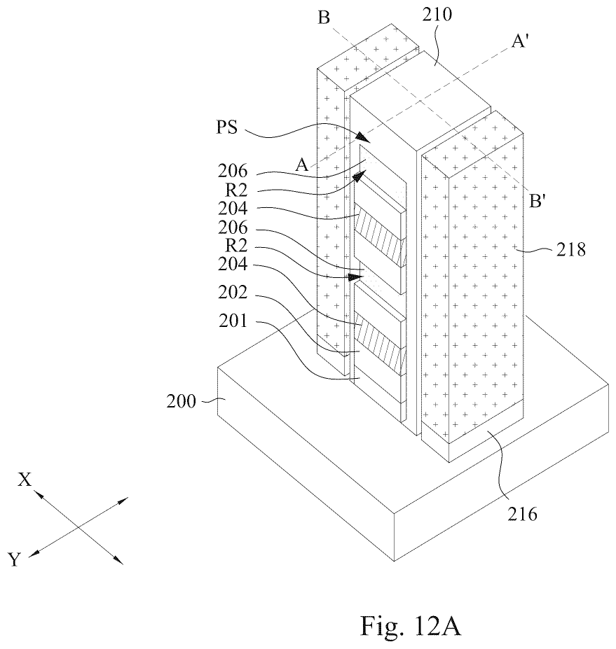

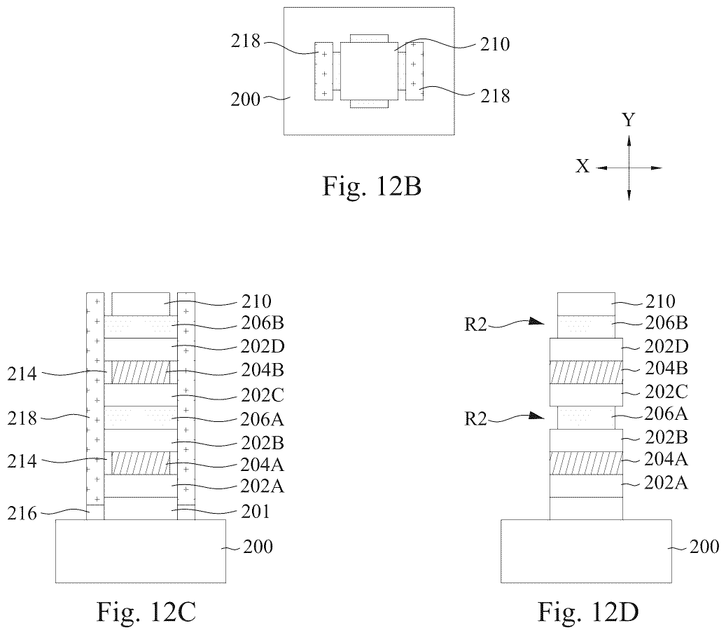

FIG. 12A is a perspective view of an intermediate stage in manufacturing of the inverter that is subsequent to the stage shown in FIG. 11A, FIG. 12B is a top view of the structure illustrated in FIG. 12A, FIG. 12C is a cross-sectional view obtained from cut A-A′ in FIG. 12A, and FIG. 12D is a cross-sectional view obtained from cut B-B′ in FIG. 12A. In FIGS. 12A-12D, X-directional sidewalls of the PFET channel layers 206 exposed by the removal of NFET source/drain regions PX in the previous step are laterally recessed by suitable etching technique to form sidewall recesses R2 between corresponding sacrificial layers 202. Although sidewalls of the PFET channel layers 206 in the recesses R2 are illustrated as being straight in FIG. 12D, the sidewalls may be concave or convex. In some embodiments, the etching step is a selective etching step performed with an etch mask (e.g., photoresist mask and/or nitride mask) formed over the p-type epitaxial source/drain structures 218. More specifically, the selective etching is performed to only X-directional sidewalls SX of the patterned stack PS by using a patterned mask that exposes the X-directional sidewalls of the patterned stack PS only.

In some embodiments where the NFET channel layers 204 are GeSi, and the PFET channel layers 206 are GeSn, the PFET channel layers 206 can be laterally etched by using a selective etching process that etches GeSn at a faster etch rate than etching GeSi. For example, the PFET channel layers 206 formed of GeSn can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch GeSn at a faster etch rate than etching GeSi. By way of example, the GeSn selective etching step may be an isotropic dry etching process using NF₃ as a main precursor gas and performed at a flow rate of the using NF₃ gas in a range from about 1 standard cubic centimeters per minute (sccm) to about 1000 sccm, at a chamber temperature in a range from about 0 degrees Centigrade to about 100 degrees Centigrade, and at a pressure in a range from about 1 torr to about 300 torr. As discussed previously about selectively etching NFET channel layers 204 formed from GeSi, the plasma etching using a fluorine-based gas can also be used to selectively etch GeSi. In that case, the GeSn selective etching process is performed at different process conditions (e.g., flow rate of fluorine-based gas, chamber temperature, and/or chamber pressure) than the GeSi selective etching process. Stated differently, process conditions can be tuned to selectively etch GeSn or GeSi.

In some embodiments where the NFET channel layers 204 are Ge: B, and the PFET channel layers 206 are un-doped GeSi or GeSn, the PFET channel layers 206 can be laterally etched by using a selective etching process that etches un-doped GeSi or GeSn at a faster etch rate than etching Ge: B. For example, the PFET channel layers 206 formed of un-doped GeSi or GeSn can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch un-doped GeSi or GeSn at a faster etch rate than etching Ge: B. In some embodiments, the PFET channel layers 206 formed of GeSn or GeSi can be selectively etched by a wet etching process using hydrogen peroxide (H₂O₂) as the wet etchant, because the etch rate in H₂O₂ etching decreases as boron concentration increases.

In some embodiments where the NFET channel layers 204 are Si, and the PFET channel layers 206 are GeSi, the PFET channel layers 206 can be laterally etched by using a selective etching process that etches GeSi at a faster etch rate than etching Si. For example, the PFET channel layers 206 formed of GeSi can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch GeSi at a faster etch rate than etching Si. As discussed previously about selectively etching NFET channel layers 204 formed from Si, the plasma etching using a fluorine-based gas can also be used to selectively etch Si. In that case, the GeSi selective etching process is performed at different process conditions (e.g., flow rate of fluorine-based gas, chamber temperature, and/or chamber pressure) than the Si selective etching process. Stated differently, process conditions can be tuned to selectively etch GeSi or Si.

In some embodiments where the NFET channel layers 204 are Ge, and the PFET channel layers 206 are GeSn, the PFET channel layers 206 can be laterally etched by using a selective etching process that etches GeSn at a faster etch rate than etching Ge. For example, the PFET channel layers 206 formed of GeSn can be selectively etched by a plasma etching using a plasma generated from a fluorine-based gas (such as CF₄, NF₃, or the like), an oxygen gas (e.g., O₂), and/or a nitrogen gas (e.g., N₂), wherein the etching conditions (e.g., flow rate of fluorine-based gas, plasma chamber temperature, and/or plasma chamber pressure) are tuned to etch GeSn at a faster etch rate than etching Ge. By way of example, the GeSn selective etching step may be an isotropic dry etching process using NF₃ as a main precursor gas and performed at a flow rate of the using NF₃ gas in a range from about 1 standard cubic centimeters per minute (sccm) to about 100 sccm, at a chamber temperature in a range from about 0 degrees Centigrade to about 100 degrees Centigrade, and at a pressure in a range from about 0 torr to about 300 torr. As discussed previously about selectively etching NFET channel layers 204 formed from Ge, the plasma etching using a fluorine-based gas can also be used to selectively etch Ge. In that case, the GeSn selective etching process is performed at different process conditions (e.g., flow rate of fluorine-based gas, chamber temperature, and/or chamber pressure) than the Ge selective etching process. Stated differently, process conditions can be tuned to selectively etch GeSn or Ge.

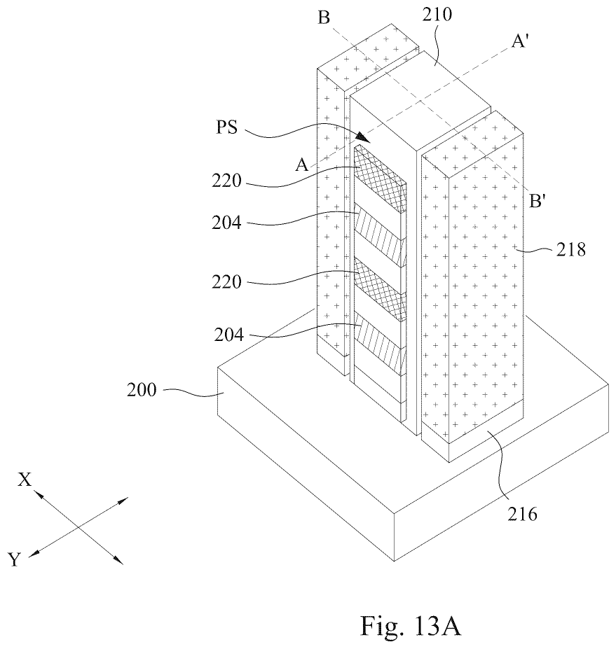

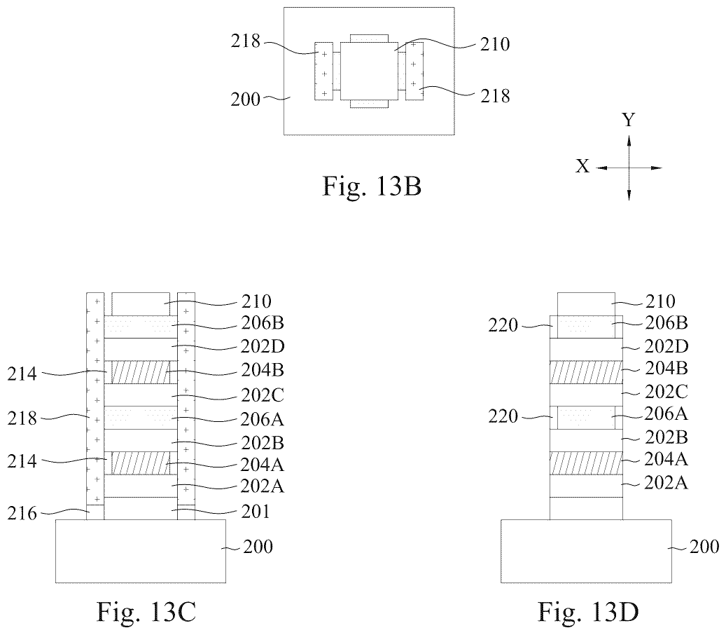

FIG. 13A is a perspective view of an intermediate stage in manufacturing of the inverter that is subsequent to the stage shown in FIG. 12A, FIG. 13B is a top view of the structure illustrated in FIG. 13A, FIG. 13C is a cross-sectional view obtained from cut A-A′ in FIG. 13A, and FIG. 13D is a cross-sectional view obtained from cut B-B′ in FIG. 13A. In FIGS. 13A-13D, after the PFET channel layers 206 are laterally recessed, NFET inner spacers 220 are formed in the sidewall recesses R2. The NFET inner spacers 220 act as isolation features between subsequently formed NFET source/drain epitaxial structures and PFET channel layers 206.

NFET inner spacers 220 are formed from an inner spacer layer that is deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 220. Although outer sidewalls of the inner spacers 220 are illustrated as being flush with sidewalls of the NFET channel layers 204 and sacrificial layers 202 as illustrated in FIG. 13D, the outer sidewalls of the inner spacers 220 may extend beyond or be recessed from sidewalls of the NFET channel layers 204 and sacrificial layers 202. Moreover, although the outer sidewalls of the inner spacers 220 are illustrated as being straight in FIGS. 13A and 13D, the outer sidewalls of the inner spacers 220 may be concave or convex. The inner spacer layer may be etched by an anisotropic etching process, such as RIE, NBE, or the like. In some embodiments, the inner spacers 220 have a thickness in a range from about 0.1 nm to about 500 nm.

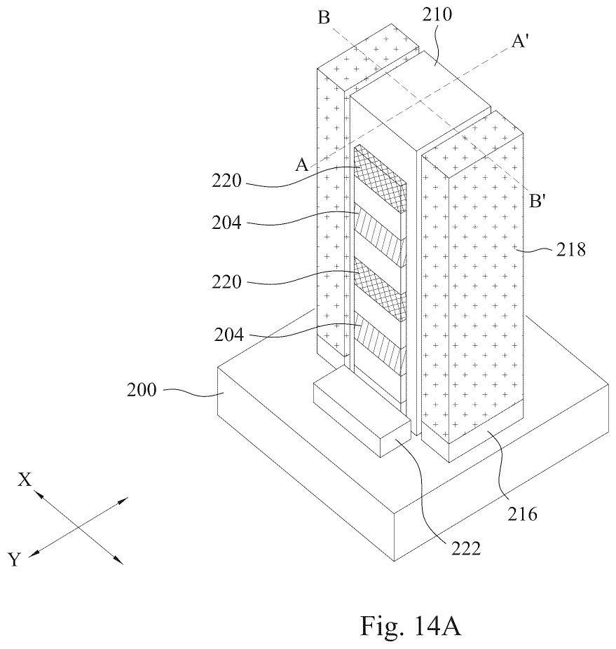

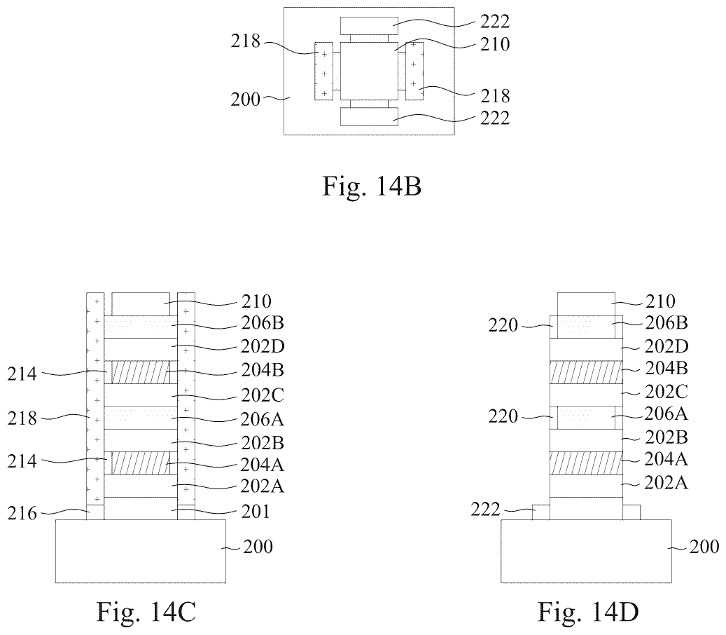

FIG. 14A is a perspective view of an intermediate stage in manufacturing of the inverter that is subsequent to the stage shown in FIG. 13A, FIG. 14B is a top view of the structure illustrated in FIG. 14A, FIG. 14C is a cross-sectional view obtained from cut A-A′ in FIG. 14A, and FIG. 14D is a cross-sectional view obtained from cut B-B′ in FIG. 14A. In FIGS. 14A-14D, bottom dielectric isolation structures 222 are formed on the substrate 200. In some embodiments, the bottom dielectric isolation structures 222 are localized to areas of previously removed NFET source/drain regions PX. In some other embodiments, the bottom dielectric isolation structures 222 cover all exposed areas of the substrate 200. The bottom dielectric isolation structures 222 can serve to electrically isolate the subsequently formed n-type source/drain epitaxial structures from the underlying substrate 200, which in turn will avoid unwanted leakage current in substrate 200 and hence unwanted shorting between source/drain epitaxial structures.

In some embodiments, the bottom dielectric isolation structures 222 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials formed by any acceptable process may be used. Once the dielectric material is deposited, the dielectric material can be selectively etched back to fall below the bottommost one of the NFET channel layers 204, which in turn allows for epitaxially growing n-type source/drain structures from the exposed surfaces of the NFET channel layers 204 directly above the bottom dielectric isolation structures 222. In some embodiments, the etched back dielectric material is patterned by using suitable photolithography and etching techniques to form bottom dielectric isolation structures 222 localized to the areas of previously removed NFET source/drain regions PX. In some embodiments, the bottom dielectric isolation structures 222 are formed from a same dielectric material as the bottom dielectric isolation structures 216 that serve to isolate the p-type epitaxial source/drain structures 218 from the substrate 200.

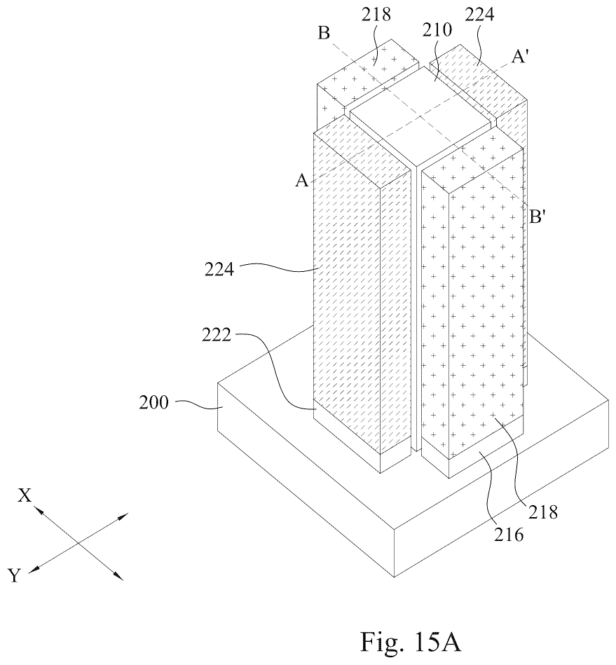

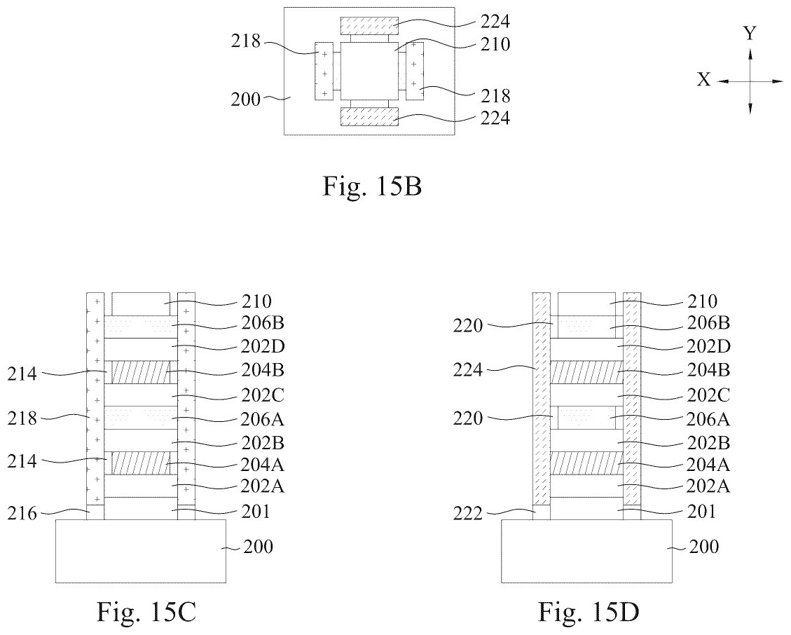

FIG. 15A is a perspective view of an intermediate stage in manufacturing of the inverter that is subsequent to the stage shown in FIG. 14A, FIG. 15B is a top view of the structure illustrated in FIG. 15A, FIG. 15C is a cross-sectional view obtained from cut A-A′ in FIG. 15A, and FIG. 15D is a cross-sectional view obtained from cut B-B′ in FIG. 15A. In FIGS. 15A-15D, n-type epitaxial source/drain structures 224 are formed on the previously removed NFET source/drain regions PX, and the NFET channel layers 204 continuously extend from a first one of the n-type epitaxial source/drain structures 224 to a second one of the n-type epitaxial source/drain structures 224. In some embodiments, the n-type epitaxial source/drain structures 224 may exert tensile strain on the NFET channel layers 204, thereby improving NFET device performance. The n-type epitaxial source/drain structures 224 are spaced apart along Y-direction, with the dummy gate structure 210 there-between. In some embodiments, the n-type epitaxial source/drain structures 224 are spaced apart from the dummy gate structure 210 because the dummy gate structure 210 has sidewalls laterally set back from the respective sidewalls of the NFET channel layers 204. In some embodiments, the inner spacers 220 are used to separate the n-type epitaxial source/drain structures 224 from the PFET channel layers 206 by an appropriate lateral distance so that the n-type epitaxial source/drain structures 224 do not short out with the PFET channel layers 206.

In some embodiments, the epitaxial source/drain structures 224 may include any acceptable material appropriate for NFET. For example, the n-type epitaxial source/drain structures 224 may comprise phosphorous-doped silicon (Si: P). In some embodiments, the epitaxial growth is performed with a patterned mask formed over the substrate 200 except for the regions directly above bottom dielectric isolation structures 222. As a result, the epitaxial growth takes place only on exposed surfaces of the NFET channel layers 204 and the sacrificial layers 202 that are exposed in the regions directly above the bottom dielectric isolation structures 222, which in turn prevents unwanted epitaxial growth taking place on other regions. In some embodiments, the epitaxy growth may be performed using CVD deposition techniques (e.g., vapor-phase epitaxy (VPE) and/or ultra-high vacuum CVD (UHV-CVD)), molecular beam epitaxy (MBE), and/or other suitable processes. In some embodiments, the n-type epitaxial structures 224 have a thickness in a range from about 1 nm to about 100 μm.

The n-type epitaxial structures 224 may be implanted with an n-type dopant (e.g., phosphorous or arsenic) to form n-type source/drain structures 224, followed by an anneal process. The resultant source/drain structures 224 may have an n-type impurity (e.g., phosphorous or arsenic) concentration of between about 1×10¹⁷ atoms/cm³ and about 1×10²² atoms/cm³. In some embodiments, the n-type epitaxial structures 224 may be in situ doped with the n-type dopant during growth.

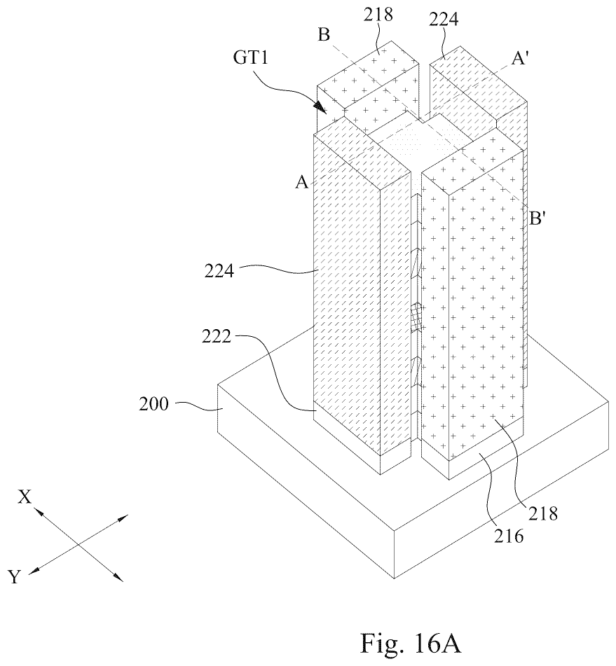

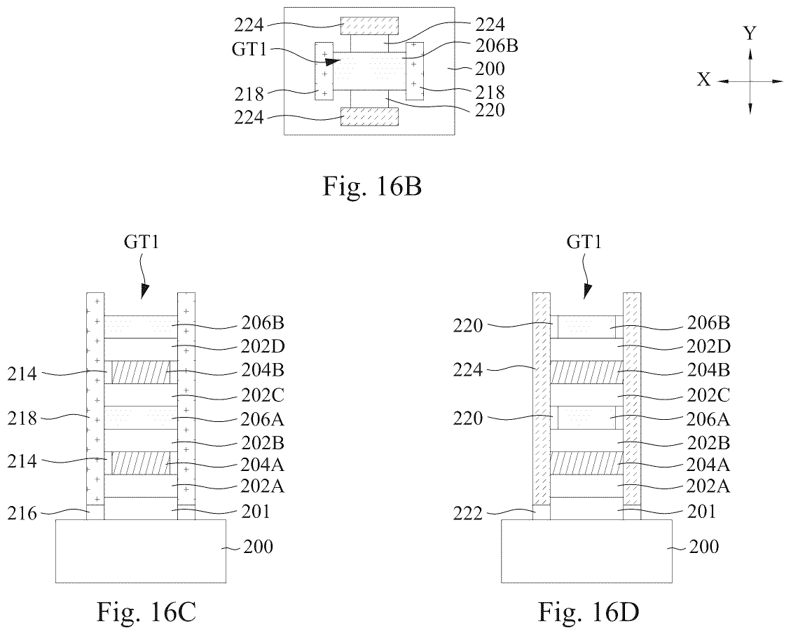

FIG. 16A is a perspective view of an intermediate stage in manufacturing of the inverter that is subsequent to the stage shown in FIG. 15A, FIG. 16B is a top view of the structure illustrated in FIG. 16A, FIG. 16C is a cross-sectional view obtained from cut A-A′ in FIG. 16A, and FIG. 16D is a cross-sectional view obtained from cut B-B′ in FIG. 16A. In FIGS. 16A-16D, the dummy gate structure 210 is removed in one or more etching steps, so that a gate trench GT1 is formed in a space surrounded by the p-type epitaxial source/drain structures 218 and the n-type epitaxial source/drain structures 224. In some embodiments, the dummy gate structure 210 is removed by an anisotropic dry etch process. For example, the etching process may include a dry etch process using reaction gas(es) that selectively etch the dummy gate structure 210 at a faster rate than etching other materials on the substrate 200. In some embodiments, the dummy gate removal etching is performed with an etch mask (e.g., photoresist mask and/or nitride mask) formed over the p-type epitaxial source/drain structures 218 and the n-type epitaxial source/drain structures 224, thus preventing unwanted damages on these source/drain structures. In some embodiments, an interlayer dielectric (ILD) is formed over the p-type epitaxial source/drain structures 218 and the n-type epitaxial source/drain structures 224 before the dummy gate removal step, and the ILD will not be removed and thus will remain in a final IC product.

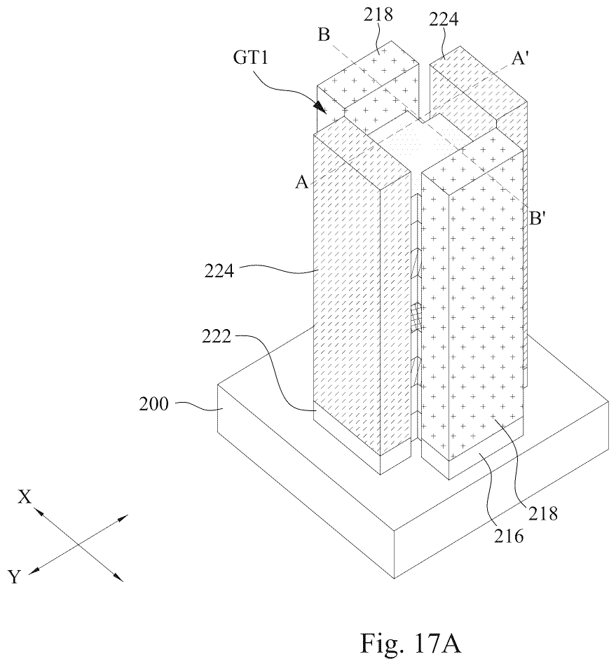

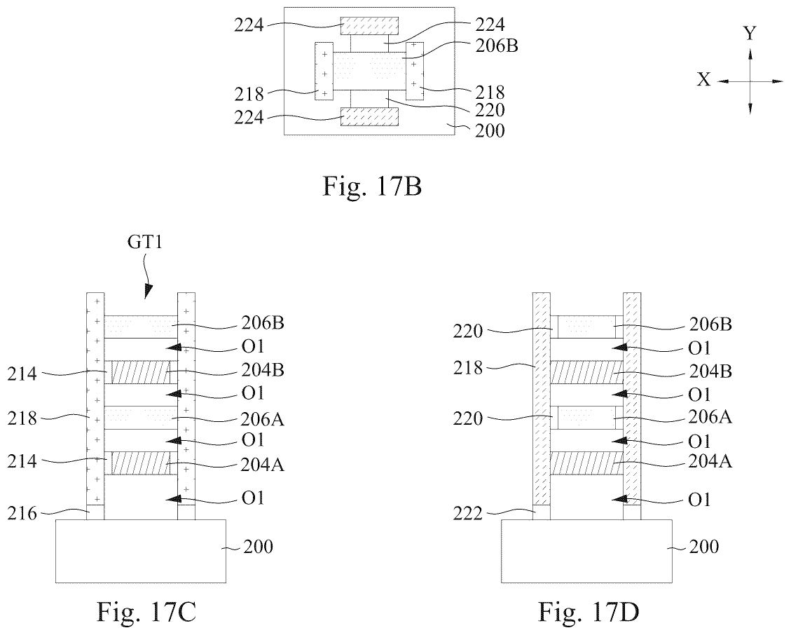

FIG. 17A is a perspective view of an intermediate stage in manufacturing of the inverter that is subsequent to the stage shown in FIG. 16A, FIG. 17B is a top view of the structure illustrated in FIG. 17A, FIG. 17C is a cross-sectional view obtained from cut A-A′ in FIG. 17A, and FIG. 17D is a cross-sectional view obtained from cut B-B′ in FIG. 17A. In FIGS. 17A-17D, the buffer layer 201 and sacrificial layers 202 are removed by a selective etching process, thus forming openings O1 each between adjacent two of the NFET channel layers 204 and PFET channel layers 206 and an opening O1 below a bottommost NFET channel layer 204A. In this way, PFET channel layers 206 become suspended over the substrate 200 and connect the p-type source/drain structures 218, and the NFET channel layers 204 also become suspended over the substrate 200 and connect the n-type source/drain structures 224. The NFET channel layers 204 and PFET channel layers 206 are alternately arranged in the gate trench GT1 and spaced apart by the openings O1.

This step can be interchangeably referred to as a channel release process. At this interim processing step, the openings O1 may be filled with ambient environment conditions (e.g., air, nitrogen, etc). The selective etching process removes the material of the buffer layer 201 and sacrificial layers 202 (e.g., Ge) at a faster rate than or without substantially etching the material of the NFET channel layers 204 (e.g., GeSi) and PFET channel layers 206 (e.g., GeSn). By way of example, the Ge selective etching step may be an isotropic dry etching process using NF₃ as a main precursor gas and performed at a flow rate of the using NF₃ gas in a range from about 1 standard cubic centimeters per minute (sccm) to about 100 sccm (e.g., 7 sccm), at a chamber temperature in a range from about 0 degrees Centigrade to about 100 degrees Centigrade (e.g., 14 degrees Centigrade), and at a pressure in a range from about 1 torr to about 100 torr (e.g., 7 torr).

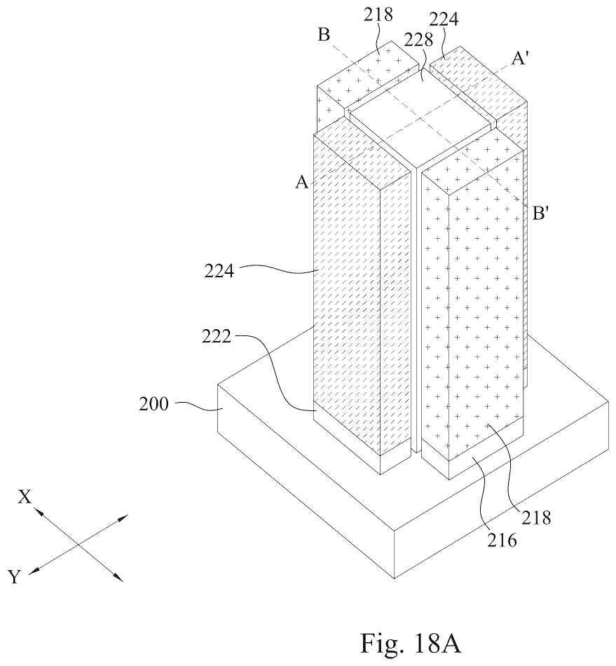

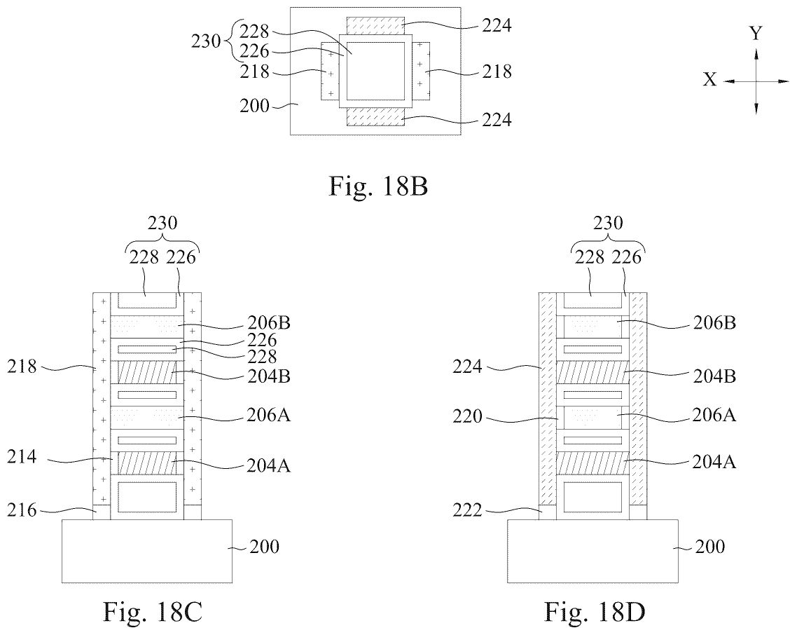

FIG. 18A is a perspective view of an intermediate stage in manufacturing of the inverter that is subsequent to the stage shown in FIG. 17A, FIG. 18B is a top view of the structure illustrated in FIG. 18A, FIG. 18C is a cross-sectional view obtained from cut A-A′ in FIG. 18A, and FIG. 18D is a cross-sectional view obtained from cut B-B′ in FIG. 18A. In FIGS. 18A-18D, a replacement gate structure 230 is formed. The replacement gate structure 230 may be a high-k/metal gate stack, however other compositions are possible. The replacement gate structure 230 forms a gate associated with multi-channels provided by the NFET channel layers 204, and also forms a gate associated with multi-channels provided by the PFET channel layers 206. The replacement gate structure 230 thus serves as a final gate for both an NFET formed from the NFET channel layers 204 and a PFET formed from the PFET channel layers 206. Stated differently, the NFET channel layers 204 and the PFET channel layers 206 share a same gate structure, and thus a gate terminal of the resultant NFET and a gate terminal of the resultant PFET are coupled together to serve as an inverter, which has a reduced footprint because of the overlapping NFET and PFET channel layers 204 and 206.

The replacement gate structure 230 is formed within the gate trench GT1 and the openings O1 provided by the release of NFET and PFET channel layers 204 and 206. In some embodiments, the replacement gate structure 230 includes a gate dielectric layer 226 formed over top and bottom surfaces of each of the NFET and PFET channel layers 204 and 206, and a metal gate 228 formed over the gate dielectric layer 226. In some embodiments, the gate dielectric layer 226 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The metal gate 228 includes one or more work function metal layers and a fill metal formed over the one or more work function metal layers. The one or more work function metal layers and the fill metal used within high-k/metal gate structure may include a metal, metal alloy, or metal silicide. Additionally, the formation of the high-k/metal gate stack may include depositions to form various gate materials, one or more liner layers, and one or more CMP processes to remove excessive gate materials. The gate dielectric layer 226 is illustrated in the top view of FIG. 18B and cross-sectional views of FIGS. 18C and 18D, and not illustrated in the perspective view of FIG. 18A for the sake of simplicity and clarity.

In some embodiments, the interfacial layer of the gate dielectric layer 226 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 226 may include hafnium oxide (HfO₂). Alternatively, the gate dielectric layer 226 may include other high-k dielectrics, such as hafnium silicon oxide (HfSiO), hafnium oxynitride (HfON), hafnium silicon oxynitride (HfSiON), hafnium tantalum oxide (HfTaO), hafnium titanium oxide (HfTiO), hafnium zirconium oxide (HfZrO), lanthanum oxide (La₂O₃), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The metal gate 228 includes one or more n-type work function metal (N-metal) layers and/or one or more p-type work function metal (P-metal) layers. The n-type work function metals may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), tungsten (W), metal carbides (e.g., hafnium carbide (HfC), zirconium carbide (ZrC), titanium carbide (TiC), aluminum carbide (AIC), tungsten carbide (WC)), aluminides, and/or other suitable materials. The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The metal gate may further include a fill metal to fill remainder of the gate trench GT1 and openings O1. The fill metal may exemplarily include, but not limited to, tungsten, aluminum, copper, nickel, cobalt, titanium, tantalum, titanium nitride, tantalum nitride, tungsten nitride, nickel silicide, cobalt silicide, TaC, TaSiN, TaCN, TiAl, TiAIN, or other suitable materials.

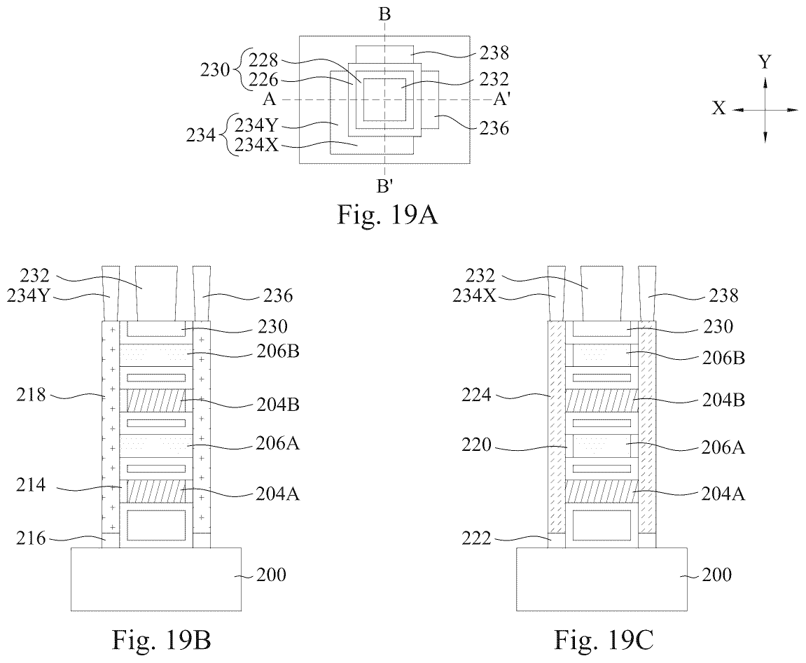

FIG. 19A is a top view of an intermediate stage in manufacturing of the inverter that is subsequent to the stage shown in FIG. 18A, FIG. 19B is a cross-sectional view obtained from cut A-A′ in FIG. 19A, and FIG. 19C is a cross-sectional view obtained from cut B-B′ in FIG. 19A. In FIGS. 19A-19C, a gate contact 232 is formed over the replacement gate structure 230, a common source/drain contact (e.g., common drain contact) 234 is formed over a first one of the p-type source/drain structures 218 (e.g., left one of the p-type source/drain structures 218 from top view in FIG. 18B) and a first one of the n-type source/drain structures 224 (e.g., lower one of the n-type source/drain structures 224 from top view in FIG. 18B), a PFET source/drain contact (e.g., PFET source contact) 236 is formed over a second one of the p-type source/drain structures 218, and an NFET source/drain contact (e.g., NFET source contact) 238 is formed over a second one of the n-type source/drain structures 224. The common source/drain contact 234 has a first portion 234Y extending along Y-direction over the first one of the p-type source/drain structures 218, and a second portion 234X extending along X-direction over the first one of the n-type source/drain structures 224. The first portion 234Y connects to a left end of the second portion 234X such that the common source/drain contact 234 has an L-shaped top-view profile. The PFET source/drain contact 236 is separated from the common source/drain contact 234 and is electrically coupled to Vdd, the NFET source/drain contact 238 is separated from the common source/drain contact 234 and is electrically coupled to ground (e.g., Vss), thereby forming an inverter. The contact 236 coupled to Vdd can be interchangeably referred to as a Vdd contact, and the contact 238 coupled to Vss can be interchangeably referred to as a Vss contact in some embodiments. As illustrated in FIGS. 19A-19C, the inverter is formed from an NFET and a PFET that share a vertically overlapping area, which in turn will reduce the footprint of the inverter to, for example, about 0.006 μm² to about 0.007 μm² (e.g., about 0.0064 μm²).

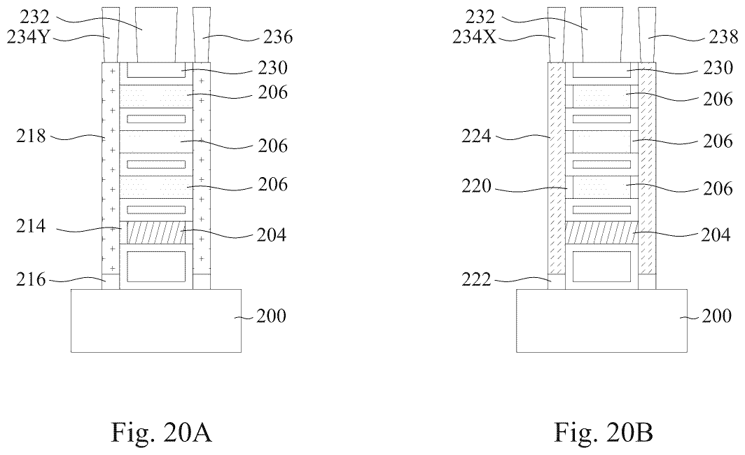

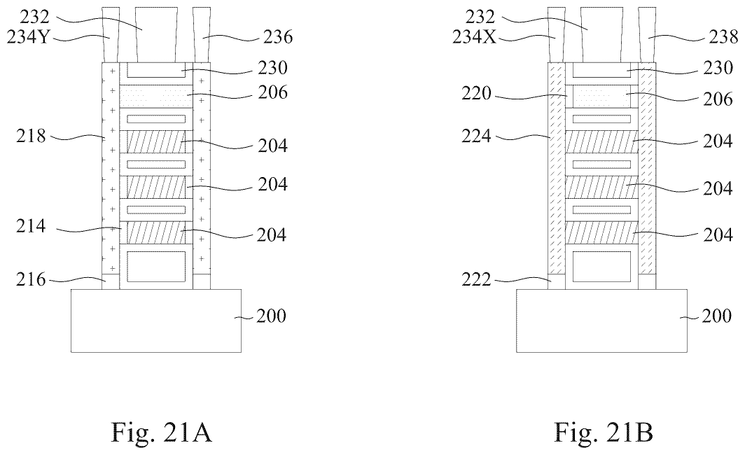

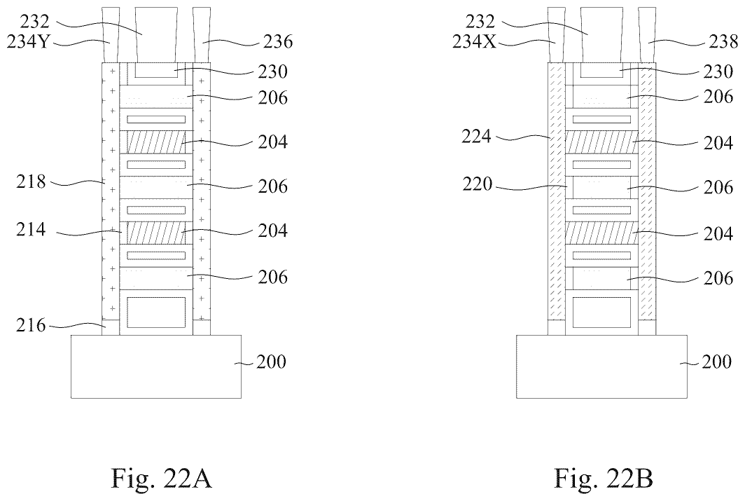

In the embodiment illustrated in FIGS. 19A-19C, the number of NFET channel layers 204 is the same as the number of PFET channel layers 206. However, in some other embodiments, the NFET channel layers and the PFET channel layers may have different number so as to balance the current in the inverter. For example, in FIGS. 20A and 20B, the inverter includes a single NFET channel layer 204 and three PFET channel layers 206 above the NFET channel layer 204. This inverter can be fabricated using similar steps as illustrated in FIGS. 2A-19C, except that in the layer stack formation step as illustrated in FIGS. 2A-2B, the epitaxy growth is modified to form a single NFET channel layers and three PFET channel layers above the NFET channel layer. Alternatively, as illustrated in FIGS. 21A and 21B, the inverter includes three NFET channel layers 204 and a single PFET channel layer 206 above the NFET channel layers 204. This inverter can be fabricated using similar steps as illustrated in FIGS. 2A-19C, except that in the layer stack formation step as illustrated in FIGS. 2A-2B, the epitaxy growth is modified to form three NFET channel layers and one PFET channel layer above the NFET channel layers. Alternatively, as illustrated in FIGS. 22A and 22B, the inverter includes alternate three PFET channel layers 206 and two NFET channel layers 204. This inverter can be fabricated using similar steps as illustrated in FIGS. 2A-19C, except that in the layer stack formation step as illustrated in FIGS. 2A-2B, the epitaxy growth is modified to alternately grow three PFET channel layers and two NFET channel layers.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the inverter has a reduced footprint because NFET and PFET of the inverter share an overlapping area and a single gate structure. Another advantage is that the vertical spacing between the NFET channel layer and the PFET channel layer can be easily controlled by a thickness of the sacrificial layer formed between the NFET channel layer and the PFET channel layer. Another advantage is that the number of PFET channel layer and the number of NFET channel layer can be selected to balance the current of invertor. Another advantage is that the cross-shaped pattern of the stack of NFET channel layers and PFET channel layers can serve to adjust NFET gate length and PFET gate length, thereby optimizing total currents of the NFET and PFET. Another advantage is that the vertically stacked NFET and PFET can be fabricated simultaneously in same front-end-of-line (FEOL) processing, and thus the thermal budges of the NFET and PFET are the same.

In some embodiments, a method comprises forming a first semiconductor layer on a substrate and a second semiconductor layer above the first semiconductor layer, the first and second semiconductor layers having first sidewalls extending along a first direction, and second sidewalls extending along a second direction different from the first direction; forming first inner spacers on the first sidewalls of the first semiconductor layer; forming p-type source/drain structures on the first sidewalls of the second semiconductor layer; forming second inner spacers on the second sidewalls of the second semiconductor layer; forming n-type source/drain structures on the second sidewalls of the first semiconductor layer; and forming a gate structure at least partially between the first and second semiconductor layers. In some embodiments, the second semiconductor layer is formed of a different material than the first semiconductor layer. In some embodiments, the first semiconductor layer has tensile strain, and the second semiconductor layer has compressive strain. In some embodiments, the method further comprises prior to forming the first inner spacers, etching the first sidewalls of the first semiconductor layer such that the first sidewalls of the first semiconductor layer are laterally set back from the first sidewalls of the second semiconductor layer. In some embodiments, the method further comprises prior to forming the second inner spacers, etching the second sidewalls of the second semiconductor layer such that the second sidewalls of the second semiconductor layer are laterally set back from the second sidewalls of the first semiconductor layer. In some embodiments, the method further comprises after forming the first inner spacers, forming bottom dielectric isolation structures on the substrate, wherein the p-type source/drain structures are respectively formed on the bottom dielectric isolation structures. In some embodiments, the method further comprises after forming the second inner spacers, forming bottom dielectric isolation structures on the substrate, wherein the n-type source/drain structures are respectively formed on the bottom dielectric isolation structures. In some embodiments, the method further comprises forming a third semiconductor layer over the first semiconductor layer before forming the second semiconductor layer, and after the p-type source/drain structures and the n-type source/drain structures are formed, removing the third semiconductor layer to form an opening between the first and second semiconductor layers, wherein the gate structure is formed at least partially in the opening between the first and second semiconductor layers. In some embodiments, the method further comprises forming a common source/drain contact electrically connecting one of the p-type source/drain structures and one of the n-type source/drain structures. In some embodiments, the common source/drain contact has an L-shaped top view profile.

In some embodiments, a method comprises forming a layer stack on a substrate, the layer stack comprising an NFET channel layer, a PFET channel layer, and a sacrificial layer between the NFET channel layer and the PFET channel layer; performing a first selective etching process to opposite first sidewalls of the layer stack, wherein the first selective etching process etches the NFET channel layer at a faster etch rate than etching the PFET channel layer; after performing the first selective etching process, forming p-type epitaxial structures on the first sidewalls of the layer stack; performing a second selective etching process to opposite second sidewalls of the layer stack, wherein the second selective etching process etches the PFET channel layer at a faster etch rate than etching the NFET channel layer; after performing the second selective etching process, forming n-type epitaxial structures on the second sidewalls of the layer stack; and replacing the sacrificial layer with a gate structure. In some embodiments, the method further comprises after performing the first selective etching process and before forming the p-type epitaxial structures, forming inner spacers on the first sidewalls of the layer stack, wherein the inner spacers are localized to the NFET channel layer. In some embodiments, the method further comprises after performing the second selective etching process and before forming the n-type epitaxial structures, forming inner spacers on the second sidewalls of the layer stack, wherein the inner spacers are localized to the PFET channel layer. In some embodiments, replacing the sacrificial layer with the gate structure comprises performing a third selective etching process to remove the sacrificial layer, leaving an opening between the PFET channel layer and the NFET channel layer; and forming the gate structure at least partially in the opening between the PFET channel layer and the NFET channel layer.

In some embodiments, a device comprises a gate structure, n-type source/drain features, p-type source/drain features, an NFET channel, and a PFET channel. The gate structure is over a substrate. The n-type source/drain features and p-type source/drain features are disposed around the gate structure. From a top view, the gate structure has a quadrilateral profile, the n-type source/drain features are respectively at opposite first and second sides of the quadrilateral profile of the gate structure, and the p-type source/drain features are respectively at opposite third and fourth sides of the quadrilateral profile of the gate structure. The NFET channel extends within the gate structure and connects the n-type source/drain features. The PFET channel extends within the gate structure and connects the p-type source/drain features. The NFET channel and the PFET channel are vertically spaced apart by the gate structure. In some embodiments, the device further comprises a first inner spacer separating the NFET channel from a first one of the p-type source/drain features, and a second inner spacer separating the NFET channel from a second one of the p-type source/drain features. In some embodiments, the device further comprises a third inner spacer separating the PFET channel from a first one of the n-type source/drain features, and a fourth inner spacer separating the PFET channel from a second one of the n-type source/drain features. The first and second inner spacers are spaced apart along a first direction, and the third and fourth inner spacers are spaced apart along a second direction different from the first direction. In some embodiments, the device further comprises a common source/drain contact electrically connecting one of the p-type source/drain features and one of the n-type source/drain features, and the common source/drain contact has an L-shaped top view profile. In some embodiments, the device further comprises a Vdd contact over one of the p-type source/drain features, and a Vss contact over one of the n-type source/drain features. From a top view the Vdd contact and the Vss contact extend along different directions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an NFET channel over a substrate;
a PFET channel at a different level than the NFET channel, the PFET channel vertically overlapping the NFET channel;
a gate structure over the NFET channel and the PFET channel;
n-type source/drain features respectively on a first side and a second side of the NFET channel;
p-type source/drain features respectively on a third side and a fourth side of the PFET channel; and
a first interposing structure interposing one of the p-type source/drain features and the substrate.

2. The device of claim 1, further comprising:
a second interposing structure interposing one of the n-type source/drain features and the substrate.

3. The device of claim 2, wherein the second interposing structure is spaced apart from the first interposing structure.

4. The device of claim 2, wherein the first interposing structure extends lengthwise along a first direction, and the second interposing structure extends lengthwise along a second direction different from the first direction.

5. The device of claim 2, wherein the second interposing structure has opposite sidewalls respectively aligned with opposite sidewalls of said one of the n-type source/drain features.

6. The device of claim 2, wherein the second interposing structure is a dielectric structure.

7. The device of claim 2, wherein an entirety of the second interposing structure is laterally offset from the gate structure.

8. The device of claim 2, wherein the second interposing structure has a thickness in a vertical direction less than a thickness of said one of the n-type source/drain features in the vertical direction.

9. The device of claim 1, wherein the first interposing structure has opposite sidewalls respectively aligned with opposite sidewalls of said one of the p-type source/drain features.

10. The device of claim 1, wherein the first interposing structure is a dielectric structure.

11. The device of claim 1, wherein an entirety of the first interposing structure is laterally offset from the gate structure.

12. The device of claim 1, wherein the first interposing structure has a thickness in a vertical direction less than a thickness of said one of the p-type source/drain features in the vertical direction.

13. A device comprising:
a first semiconductor layer disposed over a substrate, the first semiconductor layer being formed of a first semiconductor material;
a second semiconductor layer disposed over the first semiconductor layer, the second semiconductor layer being formed of a second semiconductor material different from the first semiconductor material;
a gate structure disposed over the first semiconductor layer and the second semiconductor layer;
n-type source/drain features forming first interfaces with the first semiconductor layer; and
p-type source/drain features forming second interfaces with the second semiconductor layer, wherein the second interfaces are at a different level than the first interfaces.

14. The device of claim 13, wherein in a top view, the n-type source/drain features are respectively at first and second sides of the gate structure, the p-type source/drain features are respectively at third and fourth sides of the gate structure, wherein the first and second sides of the gate structure extend along a first direction, the third and fourth sides of the gate structure extend along a second direction different from the first direction.

15. The device of claim 13, wherein in a top view, the n-type source/drain features extend lengthwise along a first direction, the p-type source/drain features extend lengthwise along a second direction different from the first direction.

16. The device of claim 13, further comprising:
a contact connecting one of the n-type source/drain features and one of the p-type source/drain features.

17. A device comprising:
a gate structure disposed over a substrate
a first channel layer disposed over the substrate;
a second channel layer disposed over the first channel layer and spaced apart from the first channel layer by the gate structure;
n-type source/drain features interfacing opposite sidewalls of the first channel layer;
p-type source/drain features interfacing opposite sidewalls of the second channel layer; and
a first contact in electrical communication with both a first one of the n-type source/drain features and a first one of the p-type source/drain features, wherein the first contact has an L-shaped profile in a top view.

18. The device of claim 17, further comprising:
a second contact in electrical communication with a second one of the n-type source/drain features; and
a third contact in electrical communication with a second one of the p-type source/drain features.

19. The device of claim 18, wherein in the top view, a lengthwise direction of the second contact is different from a lengthwise direction of the third contact.

20. The device of claim 17, further comprising:
a dielectric structure interposing the first one of the p-type source/drain features and the substrate.
